(19) United States
(12) Patent Application Publication
(10) Pub. No.: US 2024/0380187 A1
(43) Pub. Date: Nov. 14, 2024

(54) HIGH POWER GALLIUM AND NITROGEN CONTAINING LASER DIODE DEVICES WITH IMPROVED MODE QUALITY

(71) Applicant: KYOCERA SLD Laser, Inc., Goleta, CA (US)

(72) Inventors: James W. Raring, Santa Barbara, CA (US); Thiago P. Melo, Fremont, CA (US); Ryan C. White, Goleta, CA (US); Philip Chan, Goleta, CA (US); Phillip Skahan, Goleta, CA (US)

(73) Assignee: KYOCERA SLD Laser, Inc., Goleta, CA (US)

(21) Appl. No.: 18/228,633

(22) Filed: Jul. 31, 2023

Related U.S. Application Data
(60) Provisional application No. 63/465,353, filed on May 10, 2023.

(51) Int. Cl. H01S 5/50; H01S 5/026; H01S 5/042; H01S 5/10; H01S 5/125; H01S 5/40

(52) U.S. Cl. CPC H01S 5/50; H01S 5/026; H01S 5/0421; H01S 5/1014; H01S 5/125; H01S 5/4031

(57) ABSTRACT

According to the present invention, techniques for high power gallium and nitrogen containing laser diode devices are provided. Such high power devices include straight lasers, tapered lasers, distributed feedback lasers, distributed Bragg reflector laser devices, and master oscillator power amplifier devices, among others configured with improved mode quality.

### CROSS-REFERENCE TO RELATED APPLICATIONS

This application claims priority to Provisional Application No. 63/465,353, filed May 10, 2023, the entire contents of which are incorporated herein by reference for all purposes.

### BACKGROUND

Devices based on wide bandgap III-V semiconductor materials such as gallium nitride (GaN) play a major role in our modern world. They play critical roles in essentially all of our electronic devices and are instrumental in almost all of the machines and apparatus we rely on every day. Examples of such semiconductor devices include light emitting devices such as light emitting diodes and laser diodes Forming such GaN devices of the highest performance often requires epitaxial structures with minimum defect density and the highest crystal quality and purity. To achieve the low defect density and high crystal quality it is most optimum to grow the epitaxial device epitaxial layers on a native GaN substrates to form a pseudomorphic epitaxial structure that is relatively free from strain related defects that occur when growing on foreign substrates.

Unfortunately, the synthesis of GaN single crystal substrates has been an extraordinarily difficult task. The highly successful Czochralski method for silicon crystal growth would have impractical process requirements comparable to conditions very deep within the Earth's mantle. Alternative approaches have been investigated for growing GaN bulk substrates, such as hydride vapor phase epitaxy (HVPE) and ammonothermal growth. Additionally, it is still a great challenge to scale up bulk GaN growth to larger wafer sizes. GaN substrates are currently available in 2″ diameter at high volume and recent announcements have revealed availability in 4″ in the near future, which is still drastically smaller than more mature substrate technologies such as 12″ single crystal silicon. At the current GaN wafer diameter and prices, the native substrate option is not economically feasible for realizing semiconductor devices in many applications, specifically light emitting diode applications and power electronic applications. Given the obstacles in GaN native substrate manufacturing, there has been substantial effort devoted to the epitaxy on foreign substrate materials. Common choices for GaN heteroepitaxy include sapphire, silicon carbide, and silicon. In the past decade, SiC and sapphire substrates have been widely used in nitride LEDs and RF transistors.

A laser diode is a two-lead semiconductor light source that emits electromagnetic radiation that is comprised primarily of stimulated emission. The laser diode is comprised of a gain medium that functions to provide emission through the recombination of electron-hole pairs and a cavity region that functions as a resonator for the emission of the gain medium. When a suitable voltage is applied to the leads to sufficiently pump the gain medium, the cavity losses are overcome by the gain and the laser diode reaches the so-called threshold condition, wherein a steep increase in the light output versus current input characteristic is observed. Unlike LEDs, laser diodes emit very directional light and have orders of magnitude higher spatial brightness. Moreover, above threshold, they do not suffer from the droop phenomenon that plagues LEDs.

Early visible laser technology comprised lamp pumped infrared solid state lasers with the output wavelength converted to the visible using specialty crystals with nonlinear optical properties. For example, a green lamp pumped solid state laser had 3 stages: electricity powers lamp, lamp excites gain crystal which lases at 1064 nm, 1064 nm goes into frequency conversion crystal which converts to visible 532 nm. The resulting green and blue lasers were called “lamped pumped solid state lasers with second harmonic generation” (LPSS with SHG) had wall plug efficiency of ˜1%, and were more efficient than Ar-ion gas lasers, but were still too inefficient, large, expensive, fragile for broad deployment outside of specialty scientific and medical applications. To improve the efficiency of these visible lasers, high power diode (or semiconductor) lasers were utilized. These “diode pumped solid state lasers with SHG” (DPSS with SHG) had 3 stages: electricity powers 808 nm diode laser, 808 nm excites gain crystal, which lases at 1064 nm, 1064 nm goes into frequency conversion crystal which converts to visible 532 nm. As high power laser diodes evolved and new specialty SHG crystals were developed, it became possible to directly convert the output of the infrared diode laser to produce blue and green laser light output. These “directly doubled diode lasers” or SHG diode lasers had 2 stages: electricity powers 1064 nm semiconductor laser, 1064 nm goes into frequency conversion crystal which converts to visible 532 nm green light. These lasers designs are meant to improve the efficiency, cost and size compared to DPSS-SHG lasers, but the specialty diodes and crystals required make this challenging today.

Based on essentially all the pioneering work on GaN LEDs, visible laser diodes based on GaN technology have emerged. Currently the only viable direct blue and green laser diode structures are fabricated from the wurtzite AlGaInN material system. The manufacturing of light emitting diodes from GaN related materials is dominated by the heteroepitaxial growth of GaN on foreign substrates such as Si, SiC and sapphire. Laser diode devices operate at such high current densities that the crystalline defects associated with heteroepitaxial growth are not acceptable. Because of this, very low defect-density, free-standing GaN substrates have become the substrate of choice for GaN laser diode manufacturing. Unfortunately, such bulk GaN substrates are costly and not widely available in large diameters. For example, 2″ diameter is the most common bulk GaN c-plane substrate size today with recent progress enabling 4″ diameter, which are still relatively small compared to the 6″ and greater diameters that are commercially available for mature substrate technologies.

Lasers rely on feedback of light into an optical cavity. In a Fabry-Perot laser, this feedback is from facets and dielectric facet coatings which are broadband reflectors. Because the facets and coatings reflect over a broad wavelength range, many longitudinal modes are supported in the cavity. This leads to wide spectral widths in the hundreds or thousands of picometers. Some applications, for example sensing, communication or coupling into an external waveguide, benefit from narrow spectral widths or even a single longitudinal lasing mode. To achieve a single longitudinal mode or single frequency operation, narrow-band mirrors in the form of gratings provide wavelength-dependent feedback to the cavity and act as a mode filter.

### SUMMARY

Examples of the invention provide semiconductor laser diodes and methods of manufacture. Typically, these devices are fabricated using an epitaxial deposition, followed by processing steps on the epitaxial substrate and overlying epitaxial material. What follows is a general description of the typical configuration and fabrication of these devices.

In an example, the present invention provides a patterned n-type contact region(s) for high mode quality high power GaN lasers. In an example, the patterned contact can be configured with a variety of cavity designs including a straight cavity laser, a tapered cavity laser, and a Master Oscillator Power Amplifier (MOPA). In a preferred example, gallium and nitrogen containing devices are manufactured using transfer techniques, which is described in U.S. Patent Application Publication No. US-2022-0344476, which is a continuation-in-part of U.S. application Ser. No. 17/078,389, filed Oct. 23, 2020, which is a continuation of U.S. application Ser. No. 16/835,082, filed Mar. 30, 2020, which is a continuation of U.S. application Ser. No. 16/796,154, filed Feb. 20, 2020, which is a continuation of U.S. application Ser. No. 16/005,255, filed Jun. 11, 2018, which is a continuation of U.S. application Ser. No. 15/480,239, filed Apr. 5, 2017, which is a continuation of U.S. application Ser. No. 15/209,309, filed Jul. 13, 2016, which is a continuation-in-part of U.S. application Ser. No. 14/580,693, filed Dec. 23, 2014, the contents of which are incorporated herein by reference in their entirety for all purposes. In an example, such transfer techniques can facilitate manufacture of a patterned contact on an n-type contact region of the laser diode, among other devices.

In another example, the present invention provides tapered waveguide designs for high mode quality high power GaN lasers. Examples include various taper designs and master oscillator power amplifier (MOPA) designs. Examples of such lasers include multi-mode lasers and single mode MOPA lasers, each of which are configured with patterned contacts.

In another example, the present invention provides a tapered waveguide design configured with a distributed-feedback for high-mode quality, single frequency laser diodes high power GaN lasers. Examples include various taper designs and master oscillator power amplifier designs. Examples of such lasers include multi-mode lasers and single mode MOPA lasers, each of which are configured with patterned contacts.

In another example, the present invention provides patterned n-type region contacts configured with tapered waveguide designs with DFB for high-mode quality, single frequency laser diodes and high power GaN lasers. In a preferred example, such lasers include a MOPA device for single frequency, high mode quality, high power 395 nm to 550 nm lasers based on GaN.

In another example, a laser device containing a gallium and nitrogen containing material includes a carrier substrate member comprising a front side and a back side; a metal bonding material that is free from solder material overlying the front side of the carrier substrate member and configured to bond an overlying transferred material to the front side of the carrier substrate member; a p-type contact region overlying the metal bonding material and configured to form a thermal path and an electrical path to and from the metal bonding material; a p-type gallium and nitrogen containing region overlying the p-type contact region; an active region overlying the p-type gallium and nitrogen containing region, the active region comprising a plurality of quantum well regions; an n-type gallium and nitrogen containing region overlying the active region, the n-type gallium and nitrogen containing region comprising a plurality of sub-regions numbered from 1 to N, where N is an integer of 2 and greater; a waveguide configured from a portion of the n-type gallium and nitrogen containing region, the waveguide having a first end and a second end; and configured to output a laser beam from one of the first end or the second end; a stripe region configured from an upper surface of the waveguide; an n-type contact region overlying the stripe region; and a spatial pattern disposed on the n-type contact region and configured with a dimension and a geometry to achieve a predetermined mode quality (“M2”).

In an example, the spatial pattern is selected from one or more contained squares, one or more annular regions, one or more edge square regions, one or more lattice regions, one or more ladder regions, one or more column region configured in a direction of the waveguide.

In an example, the spatial pattern is selected from an n-chip pattern, a longitudinal modulated pattern, a lateral modulated pattern, or any combinations thereof.

In an example, the n-type gallium and nitrogen containing region is selected from GaN, AlGaN, or InAlGaN comprising an impurity ranging from 1E17 cm⁻³ to about 5E19 cm⁻³.

In an example, the impurity comprises a silicon material.

In an example, the n-type gallium and nitrogen containing region has a thickness of one or more layers ranging from 1 nanometer to 1 micrometer.

In an example, the n-type gallium and nitrogen containing region, the n-type contact region are characterized by a total thickness of 100 nanometer to 3 micrometer.

In an example, the spatial pattern is configured to achieve a current injection pattern and maintain a filamenting characteristic of the device.

In an example, the spatial pattern is configured to reduce a level of optical damage to a cavity region.

In an example, the spatial pattern is configured to enhance a beam quality from a first level to a second level.

In an example, the spatial pattern is configured to provide a uniform spot size for a laser beam propagating through the waveguide.

In an example, each of the plurality of sub-regions is doped with an impurity having a concentration ranging from 1E17 to 1E20 cm⁻³.

In an example, the concentration is characterized by a profile that is graded, uniform, stepped, continuous, non-continuous, or any combinations thereof.

In an example, the spatial pattern has a first region configured for no direct current injection from the n-type contact region; and has a second region configured for direct current injection from the n-type contact region.

In an example, the waveguide is characterized by a tapered waveguide structure configured as a mesa structure.

In an example, the spatial pattern is configured within an edge of the tapered waveguide structure.

In an example, the device is characterized by a power ranging from 1 Watt to 20 Watt.

In an example, M2 is 1.

In an example, the metal bonding material comprises a metal to metal bond interface region.

In an example, the waveguide is characterized by a linear continuous taper section, a bow tie taper shape, a straight section coupled to a continuous taper section, a straight section configured between a pair of tapered sections to form a bow tie shape.

In an example, the waveguide is characterized by a width ranging from 1 micron to 10 micron or a width ranging from 5 micron to 100 micron.

In an example, the waveguide is characterized by a length.

In an example, the waveguide has a width configured in a linear manner, an exponential manner, a non-linear manner, or any combinations thereof.

In an example, the device includes one or more grating structures configured with the waveguide.

In an example, the waveguide is configured with a width to achieve a spatial mode such that a narrower width relates to a single spatial mode and a wider with relates to multiple modes.

In an example, the waveguide comprises a first region configured as a master oscillator device and a second region coupled to the first region configured as a power amplifier such that the first region and the second region are characterized as a master power amplifier device.

In an example, the waveguide comprises first region comprises a plurality of grating structures configured as a distributed feedback structure and a second region configured as an amplifier device.

In an example, the waveguide comprises a first region configured as a distributed Bragg reflector device and a second region configured as an amplifier device.

In an example, the device is one of a plurality of devices configured as a plurality of laser bars in parallel configuration.

In an example, the waveguide comprises a first region configured with an antireflective coating on the first facet and a second region configured with an antireflective coating on the second facet.

In an example, the first end and the second end include mirrors to form a cavity, the cavity configured to propagate electromagnetic radiation through the cavity and output the laser beam from one of the first end or the second end.

In another example, a laser device containing a gallium and nitrogen containing material includes a carrier substrate member comprising a front side and a back side; a metal bonding material that is free from solder material overlying the front side of the carrier substrate member and configured to bond an overlying transferred material to the front side of the carrier substrate member; a p-type contact region overlying the metal bonding material and configured to form a thermal path and an electrical path to and from the metal bonding material; a p-type gallium and nitrogen containing region overlying the p-type contact region; an active region overlying the p-type gallium and nitrogen containing region, the active region comprising a plurality of quantum well regions; an n-type gallium and nitrogen containing region overlying the active region, the n-type gallium and nitrogen containing region comprising a plurality of sub-regions numbered from 1 to N, where N is an integer of 2 and greater; an optical waveguide configured between a pair of ends configured on each side of the optical waveguide; a length characterizing the optical waveguide; a lateral width characterizing the optical waveguide; a pair of edge regions along the length characterizing each side of the optical waveguide and configured from a portion of the n-type gallium and nitrogen containing material, a portion of the p-type gallium and nitrogen containing material, or a combination of the p-type gallium and nitrogen containing material and the n-type gallium and nitrogen containing material; a stripe region configured from an upper surface of the optical waveguide and characterized by the lateral width and length of the optical waveguide; an n-type contact region overlying the stripe region; and a tapered waveguide characterizing a portion of the optical waveguide.

In an example, the device comprises a spatial pattern disposed on the n-type contact region and configured with a dimension and a geometry to achieve a predetermined mode quality (“M2”).

In an example, the spatial pattern is selected from one or more contained squares, one or more annular regions, one or more edge square regions, one or more lattice regions, one or more ladder regions, one or more column region configured in a direction of the optical waveguide.

In an example, the spatial pattern is selected from an n-chip pattern, a longitudinal modulated pattern, a lateral modulated pattern, or any combinations thereof.

In an example, the n-type gallium and nitrogen containing region is selected from GaN, AlGaN, or InAlGaN comprising an impurity ranging from 1E17 cm⁻³ to about 5E19 cm⁻³.

In an example, the impurity comprises a silicon material.

In an example, the n-type gallium and nitrogen containing region has a thickness of one or more layers ranging from 1 nanometer to 1 micrometer.

In an example, the n-type gallium and nitrogen containing region, the n-type contact region are characterized by a total thickness of 100 nanometer to 3 micrometer.

In an example, the spatial pattern is configured to achieve a current injection pattern and maintain a filamenting characteristic of the device.

In an example, the spatial pattern is configured to reduce a level of optical damage to a cavity region.

In an example, the spatial pattern is configured to enhance a beam quality from a first level to a second level.

In an example, the spatial pattern is configured to provide a uniform spot size for a laser beam propagating through the optical waveguide.

In an example, each of the plurality of sub-regions is doped with an impurity having a concentration ranging from 1E17 to 1E20 cm⁻³.

In an example, wherein the concentration is characterized by a profile that is graded, uniform, stepped, continuous, non-continuous, or any combinations thereof.

In an example, the spatial pattern has a first region configured for no direct current injection from the n-type contact region; and has a second region configured for direct current injection from the n-type contact region.

In an example, the tapered waveguide is configured as a mesa structure.

In an example, the device is characterized by a power ranging from 1 Watt to 20 Watt.

In an example, M2 is 1.

In an example, the metal bonding material comprises a metal to metal bond interface region.

In an example, the tapered waveguide is characterized by a linear continuous taper section, a bow tie taper shape, a straight section coupled to a continuous taper section, a straight section configured between a pair of tapered sections to form a bow tie shape.

In an example, the later width ranges from 1 micron to 10 micron or the lateral width ranges from 5 micron to 100 micron.

In an example, the tapered waveguide is configured with a shape structured in a linear manner, an exponential manner, a non-linear manner, or any combinations thereof.

In an example, the device further comprises one or more grating structures configured with the optical waveguide.

In an example, the optical waveguide includes a cavity region configured with a width to achieve a spatial mode such that a narrower width relates to a single spatial mode and a wider width relates to multiple modes.

In an example, the optical waveguide comprises a first region configured as a master oscillator device and a second region coupled to the first region configured as a power amplifier such that the first region and the second region are characterized as a master power amplifier device.

In an example, the optical waveguide comprises first region comprises a plurality of grating structures configured as a distributed feedback structure and a second region configured as an amplifier device.

In an example, the optical waveguide comprises a first region configured as a distributed Bragg reflector device and a second region configured as an amplifier device.

In an example, the device is one of a plurality of devices configured as a plurality of laser bars in parallel configuration.

In an example, the optical waveguide comprises a first region configured with an antireflective coating on the first facet and a second region configured with an antireflective coating on the second facet.

In an example, the optical waveguide comprises the tapered region and a non-tapered region, and a free space gap defined between the tapered region and the non-tapered region.

In another example, a master oscillator power amplifier device containing a gallium and nitrogen containing material includes a carrier substrate member comprising a front side and a back side; a metal bonding material that is free from solder material overlying the front side of the carrier substrate member and configured to bond an overlying transferred material to the front side of the carrier substrate member; a p-type contact region overlying the metal bonding material and configured to form a thermal path and an electrical path to and from the metal bonding material; a p-type gallium and nitrogen containing region overlying the p-type contact region; an active region overlying the p-type gallium and nitrogen containing region, the active region comprising a plurality of quantum well regions; an n-type gallium and nitrogen containing region overlying the active region, the n-type gallium and nitrogen containing region comprising a plurality of sub-regions numbered from 1 to N, where N is an integer of 2 and greater; a waveguide configured from a portion of the n-type gallium and nitrogen containing region, the waveguide having a first end and a second end; and configured to output a laser beam from one of the first end or the second end; a stripe region configured from an upper surface of the waveguide; an n-type contact region overlying the stripe region; and a first region of the waveguide configured as a master oscillator device and a second region configured as a first power amplifier and coupled to the first region such that the first region and the second region are characterized as the master oscillator first power amplifier device.

In an example, the device further comprises a spatial pattern disposed on the n-type contact region and configured with a dimension and a geometry to achieve a predetermined mode quality (“M2”).

In an example, the spatial pattern is selected from one or more contained squares, one or more annular regions, one or more edge square regions, one or more lattice regions, one or more ladder regions, one or more column region configured in a direction of the waveguide.

In an example, the spatial pattern is selected from an n-chip pattern, a longitudinal modulated pattern, a lateral modulated pattern, or any combinations thereof.

In an example, the n-type gallium and nitrogen containing region is selected from GaN, AlGaN, or InAlGaN comprising an impurity ranging from 1E17 cm⁻³ to about 5E19 cm⁻³.

In an example, the impurity comprises a silicon material.

In an example, the n-type gallium and nitrogen containing region has a thickness of one or more layers ranging from 1 nanometer to 1 micrometer.

In an example, the n-type gallium and nitrogen containing region, the n-type contact region are characterized by a total thickness of 100 nanometer to 3 micrometer.

In an example, the spatial pattern is configured to achieve a current injection pattern and maintain a filamenting characteristic of the device.

In an example, the spatial pattern is configured to reduce a level of optical damage to a cavity region.

In an example, the spatial pattern is configured to enhance a beam quality from a first level to a second level.

In an example, the spatial pattern is configured to provide a uniform spot size for a laser beam propagating through the waveguide.

In an example, each of the plurality of sub-regions is doped with an impurity having a concentration ranging from 1E17 to 1E20 cm⁻³.

In an example, the concentration is characterized by a profile that is graded, uniform, stepped, continuous, non-continuous, or any combinations thereof.

In an example, the spatial pattern has a first region configured for no direct current injection from the n-type contact region; and has a second region configured for direct current injection from the n-type contact region.

In an example, the waveguide is characterized by a tapered waveguide structure configured as a mesa structure.

In an example, the device further comprises a spatial pattern is configured within an edge of the tapered waveguide structure.

In an example, the device is characterized by a power ranging from 1 Watt to 20 Watt.

In an example, M2 is 1.

In an example, the metal bonding material comprises a metal to metal bond interface region.

In an example, the waveguide is characterized by a linear continuous taper section, a bow tie taper shape, a straight section coupled to a continuous taper section, a straight section configured between a pair of tapered sections to form a bow tie shape.

In an example, the waveguide is characterized by a width ranging from 1 micron to 10 micron or a width ranging from 5 micron to 100 micron.

In an example, the waveguide is characterized by a length.

In an example, the waveguide has a width configured in a linear manner, an exponential manner, a non-linear manner, or any combinations thereof.

In an example, the device further comprises one or more grating structures configured with the waveguide.

In an example, the waveguide is configured with a width to achieve a spatial mode such that a narrower width relates to a single spatial mode and a wider width relates to multiple modes.

In an example, the waveguide comprises first region comprises a plurality of grating structures configured as a distributed feedback structure and a second region configured as an amplifier device.

In an example, the waveguide comprises a first region configured as a distributed Bragg reflector device and a second region configured as an amplifier device.

In an example, the device is one of a plurality of devices configured as a plurality of laser bars in parallel configuration.

In an example, the waveguide comprises a first region configured with an antireflective coating on the first facet and a second region configured with an antireflective coating on the second facet.

In an example, the first region is characterized by a straight waveguide and the second region is characterized by a tapered waveguide.

In an example, the device further comprises a current isolation region configured between the first portion and the second portion to electronically isolate the first portion from the second portion.

In an example, the device further comprises a plurality of current isolation regions configured spatially in the second portion to create separate current injection regions, each of the separate current injection regions configured with a separate patterned spatial contact.

In an example, the device further comprises a third portion configured as a second power amplifier operably coupled to the first power amplifier and configured with a free space configured between the second portion and the third portion to separate the first portion from the second portion by a gap.

In an example, the device further comprises a third portion configured as a second power amplifier operably coupled to the first power amplifier and configured with a free space configured between the second portion and the third portion to separate the first portion from the second portion by a gap, the gap comprising a fill material.

In an example, the device further comprises a third portion configured as a second power amplifier, the second power amplifier comprising an antireflective coating on an aperture portion, and an antireflective portion coating on an exit portion.

In an example, the device further comprises a third portion configured as a second power amplifier, the third portion operably coupled to the second portion, the second power amplifier comprising an antireflective coating on an aperture portion, and an antireflective portion coating on an exit portion; and further comprising a plurality of grating structures configured within a vicinity of an exit region of the second power amplifier.

In an example, the device further comprises a third portion configured as a second power amplifier, the third portion operably coupled to the second portion, the second power amplifier comprising an antireflective coating on an aperture portion, and an antireflective portion coating on an exit portion, the third portion and the second portion being configured with a spatial gap between the first portion and the second portion; and further comprising an optical element configured within the spatial gap.

In an example, the device further comprises a third portion configured as a second power amplifier, the third portion operably coupled to the second portion, the third portion and the second portion being configured with a spatial gap between the first portion and the second portion; and further comprising a lens facet on the second portion facing the third portion.

In an example, the device further comprises a third portion configured as a second power amplifier, the third portion operably coupled to the second portion, the third portion and the second portion being configured with a spatial gap between the first portion and the second portion; and further comprising a plurality of current isolation regions spatially disposed along a length of the third portion, each pair of current isolation regions configured to form a separate current injection zone, each current injection zone comprising a spatially patterned contact region.

In an example, the device further comprises a third portion configured as a second power amplifier, the third portion operably coupled to the second portion, the third portion and the second portion being configured with a spatial gap between the first portion and the second portion; and wherein the first portion comprises an angled facet region.

In an example, the device further comprises a third portion configured as a second power amplifier, the third portion operably coupled to the second portion, the third portion and the second portion being configured with a spatial gap between the first portion and the second portion and the third portion having a length configured at an angle of less than 180 Degrees from a length of the waveguide.

In an example, the first portion and the second portion are configured with a spatial gap between the first portion and the second portion.

In an example, the first end and the second end include mirrors to form a cavity, the cavity configured to propagate electromagnetic radiation through the cavity and output the laser beam from one of the first end or the second end.

Various benefits and/or advantages are achieved using one or more aspects of the present invention. In an example, a combination of patterned n-region contacts and novel transfer techniques offer one or more advantages as follows:
1. Improved reliability: In an example, patterned n-region contacts reduce a risk of catastrophic optical damage (COD) in high-power lasers. As COD rate is proportional to the optical power density at the facet, reduction in local power density causes a simultaneous reduction in COD rate. Optical damage occurs when the laser output power causes thermal damage to the laser facet, which can lead to device failure. By reducing the areas of high optical power density caused from filamentation, patterned n-type region contacts reduce a risk of optical damage and improve the reliability of the laser.
2. Enhanced beam quality: In an example, reduced filamentation and superior mode control offered by patterned n-region contacts enabled by present transfer techniques can improve the beam quality of the laser, leading to a narrower and more stable output beam.
3. Optical Profile: Reduction of filamentation creates a manageable, uniform near-field intensity pattern for uniform spot size.
4. In other non-laser diode devices, patterned n-region contacts enabled by present techniques reduces optical losses due to reflection or shading in devices that rely on light absorption such as, for example, solar cells and photo detectors.

In an example, the present laser diode having patterned n-region contacts improves manufacturing efficacy and reliability of semiconductor lasers and accessing higher output power more reliably, particularly high-power single-mode lasers.

The present invention achieves these benefits and others in the context of known process technology. However, a further understanding of the nature and advantages of the present invention may be realized by reference to the latter portions of the specification and attached drawings.

### BRIEF DESCRIPTION OF THE DRAWINGS

FIG. 1 is a simplified diagram of a conventional laser device.

FIG. 2 is a simplified side view diagram of an edge emitting laser diode according to an example of the present invention.

FIG. 3 is a more detailed diagram illustrating an n-type region, including sub-regions, for a laser diode according to an example of the present invention.

FIG. 4 is an image of a ridge structure including patterned contact for a laser diode according to an example of the present invention.

FIG. 5 is a top-view diagram of various patterned contact regions according to an example of the present invention.

FIG. 6 is a top-view diagram of alternative patterned contact regions according to an example of the present invention.

FIG. 7 is a top-view diagram of alternative patterned contact regions according to an example of the present invention.

FIG. 8 is a simplified side-view diagram of a laser diode according to an example of the present invention.

FIG. 9 is a simplified side-view diagram of a laser diode according to an example of the present invention.

FIG. 10 is a simplified top-view diagram of a tapered waveguide laser device according to an example of the present invention.

FIG. 11 is a simplified top view diagram of a straight laser diode configured with a tapered waveguide laser diode according to an example of the present invention.

FIG. 12 is a simplified illustration of images of tapered waveguide laser diodes according to an example of the present invention.

FIG. 13 is a simplified illustration of mask devices for a tapered waveguide laser diode according to an example of the present invention.

FIG. 14 is a simplified illustration of various patterned contact regions of tapered waveguide laser diodes according to examples of the present invention.

FIG. 15 is a simplified illustration of a distributed feedback laser diode device according to an alternative example of the present invention.

FIG. 16 is a simplified illustration of a distributed feedback laser diode device according to an alternative example of the present invention.

FIG. 17 is a simplified side-view diagram of a MOPA device according to an example of the present invention.

FIG. 18 is a simplified top-view diagram of a MOPA device configured with a tapered amplifier according to an example of the present invention.

FIG. 19 is a simplified perspective-view diagram of a tapered waveguide laser diode device according to an example of the present invention.

FIG. 20 is a simplified top-view diagram of a MOPA device configured with a single frequency according to an example of the present invention.

FIG. 21 is a simplified top-view diagram of a MOPA device configured with a distributed feedback reflector and a distributed Bragg reflector according to an example of the present invention.

FIG. 22 is a simplified top-view diagram of a single frequency laser diode device configured with a distributed feedback reflector according to an example of the present invention.

FIG. 23 illustrates a MOPA or taped waveguide laser device configured with various patterned contact regions according to an example of the present invention.

FIGS. 24 to 29 illustrate various view of an array of lasers or MOPAs that are configured as laser bars according to examples of the present invention.

FIG. 30 illustrates schematic representation of four main methods of incoherent beam combining according to an example of the present invention.

FIG. 31 is a simplified general schematic illustration of coherent beam combining (CBC) according to an example of the present invention.

FIGS. 32-43 are simplified top-view and cross-sectional diagrams of MOPA devices according to examples of the present invention.

FIGS. 44-46 are simplified top-view and block diagrams of MOPA devices and example optics according to examples of the present invention.

### DETAILED DESCRIPTION

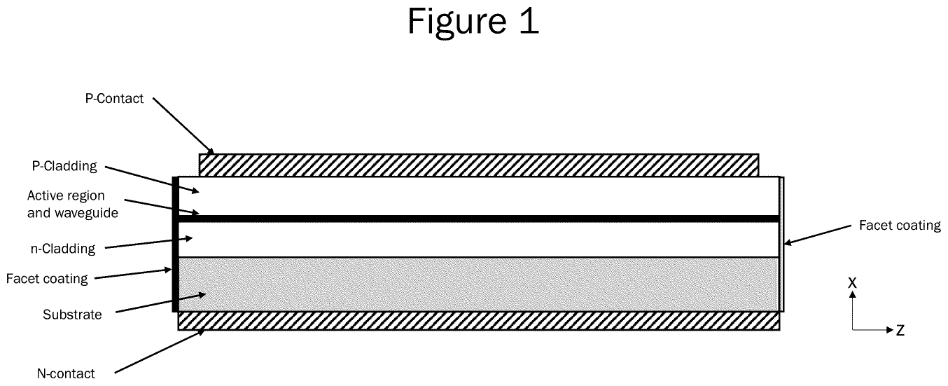

FIG. 1 is a simplified diagram of a conventional laser diode device. As shown, the conventional device has a p-type region forming a p-type contact, which faces out, and an n-type region is formed underlying a substrate member. Although useful for certain applications, the conventional device has limitations. That is, the conventional device is not operable efficiently at high order modes, high power, and other performance variations.

As the cavity width is increased a laser diode will support higher order spatial (lateral) modes beyond the fundamental mode that a single mode operates with. These higher order modes can degrade the laser beam quality as measured by the beam quality factor (m2). This limits the brightness of the laser or the degree to which the beam can be focused for a given beam divergence angle. The mode quality and brightness can be degraded for various reasons including higher slow axis divergences angles of the higher order mode, which reduces brightness, filamenting, and thermal lensing.

In single lateral mode GaN laser devices with narrow waveguides [1-3 um], the mode quality and divergence are controlled through the lateral waveguide design, the epitaxial layer design, and with uniform electrical and material properties. However, uniform narrow waveguide single mode laser devices in GaN are limited to optical output powers of less than about 500 mW or less than about 1 W, making them undesirable for reliable, high-power applications where multiple watts, kilowatts, or even megawatts are needed.

To scale the power of the laser diodes, multi-mode lasers with wider stripe dimensions of >3 um, >10 um, >30 um, >60 um, or even >100 um are often deployed. In these multimode high power devices, the mode quality and the brightness often suffer. To improve the mode quality there are several practices that can be implemented such as suppressing higher order modes, suppressing filamentation or thermal lensing, or modifying the waveguide design using approaches such as tapering which filters higher order lateral modes and can even enable single spatial mode operation.

For single frequency devices that operate both with single lateral and a single cavity [longitudinal] mode, the challenge is even in achieving high power while maintaining good mode quality. In high power single frequency devices designs must be implemented to maintain a single lateral mode such as with a waveguide taper AND maintain a single cavity mode such as with distributed Bragg reflectors (DBR) or distributed feedback (DFB) structures. In one example, a master oscillator power amplifier (MOPA) using a DFB as the seed laser/master oscillator is used to form a high-power single frequency laser. Further details of the present invention and techniques to overcome one or more of the aforementioned limitations are provided throughout the present specification and more particularly below.

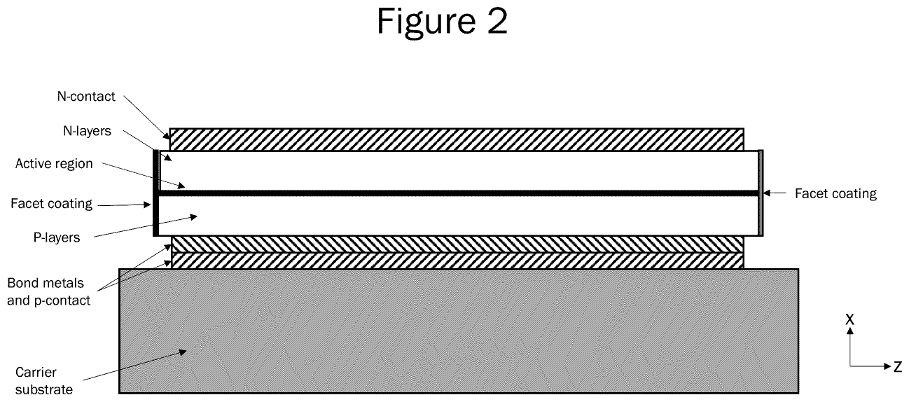

FIG. 2 is a simplified side view diagram of an edge emitting laser diode according to an example of the present invention. As shown, N-contact is on top of the transferred epi layers and p-type region contact is on the bottom of the transferred epi layers. The p-type region contact metal is within a metal stack that includes the bond metals and is bonded to a metal layer that is contained within a metal stack on the carrier substrate to create a bond interface. The edge emitting laser diode is free from a substrate used for epitaxial growth of gallium and nitrogen containing epitaxial layers. In some embodiments, the metal stack on the carrier substrate is free from solder material. In this configuration the n-type region contact and p-type region contact are deposited directly on epitaxial layers and are configured on the top and bottom of the laser cavity and are spatially aligned so that one is at least partially overlying the other. An example of a manufacturing process to fabricate the edge emitting laser diode is described in the aforementioned patents and applications, commonly assigned and hereby incorporated by reference in its entirety.

In a preferred example, the present laser diode is configured with patterned contact regions for a p-type region contact. In an example, the present contact regions can be patterned with selected dimensions, shapes, and geometries in combination with n-type region epitaxial layers between the n-type contact region and the active region of the laser diodes. In an example, the layers preferably are comprised of GaN, AlGaN, InAlGaN, or any combination. Such layers are also introduced with impurities to dope intentionally with an n-type species such as silicon, and others. In an example, such layers include one or more regions with various doping levels ranging from about 1E17 cm−3 to about 5E19 cm−3, or concentrations in between. The separate layer thicknesses could range from about 1 nm to about 1 um, and the total thickness could range from about 100 nm to about 3 μm. The thicknesses, composition, and doping levels in design with the metal or conductive oxide contacts would dictate the current injection pattern, and hence the mode quality.

In an example, the present laser diode configured with patterned n-region contacts improves optical mode quality. In an example, patterning the n-region contacts modulates the current injection pattern into the laser diode to control mode stability and prevent filamenting of the laser diode or amplifier region.

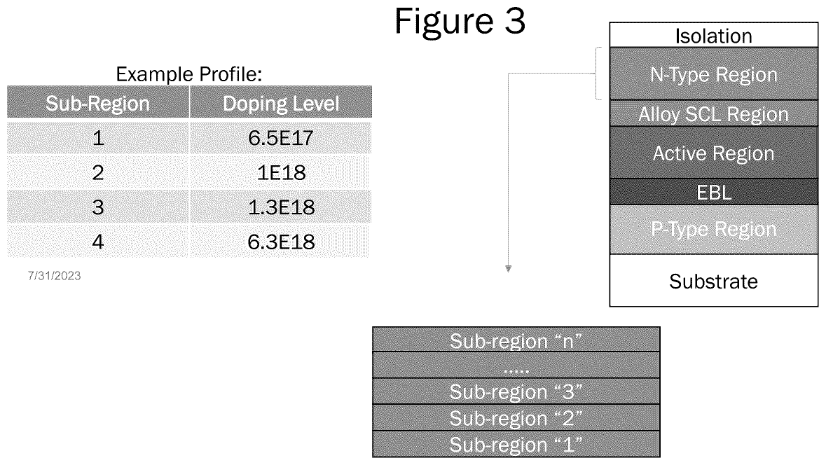

FIG. 3 is a more detailed diagram illustrating an n-type region, including sub-regions, for a laser diode according to an example of the present invention. As shown, the laser diode includes an upper n-type region and overlying isolation region. The n-type region can be continuous or have a plurality of sub regions. In an example, the n-type region is designed with different thicknesses and doping using silicon, for example, to achieve desirable current spreading for injection into an underlying active region. In an example, doping level of the n-type region may vary from 1E17 to 1E20 cm⁻³ of n-type species dopant, e.g., silicon. In an example, any n-type dopant entity can be used, although silicon species are desirable. In an example, the doping profile can vary. For example, the doping profile for the n-type region may or may not be uniform, or the doping profile for the n-type region may or may not be graded, or the n-type region may be broken into sub-regions of different doping level(s) to create a nonuniform profile or uniform doping profile. In an example, the type and number of sub regions and doping profiles may vary. That is, the doping profile may or may not be continuous and/or smooth, or the doping profile can have other variations.

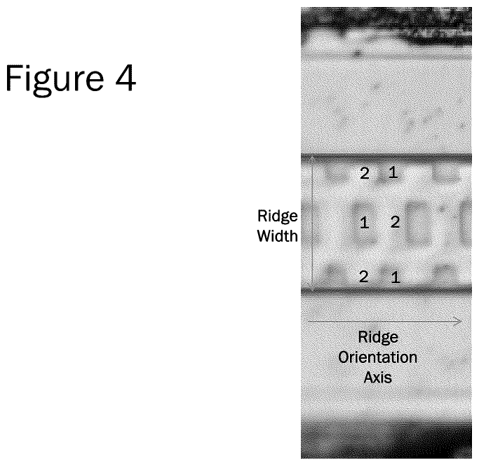

FIG. 4 is an image of a ridge structure including patterned contact for a laser diode according to an example of the present invention. In an example, the image illustrates dependence of index of refraction on modal gain/loss, carrier density, and temperature results in non-linear effects such as filamentation and spatial hole burning.

In an example, the image illustrates an Indication that patterning of the contact electrodes on laser diodes provide modulation of current density in the active region. In an example, an open region in the pattern has no direct current injection at the contact regions. A contact material has direct current injection at contacts. In an example, a strength of modulation will depend on current spreading of n-side cladding layers and a contact fill factor. In an example, modulation of current in the active region will induce gain modulation and consequently variation of refractive index.

As shown, by alternating the patterns along a ridge structure along a direction of the axis, we achieve different order waveguide modes favored by the current/gain modulation at each point. Any filamentation or non-uniform variation of waveguide mode shape tends to be desirably suppressed.

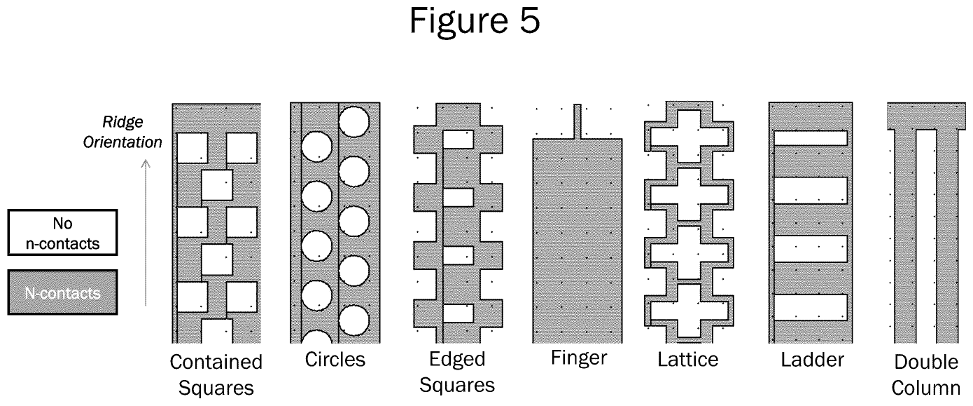

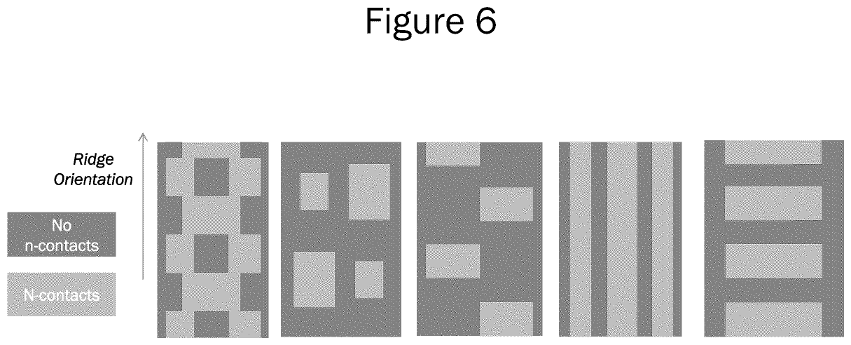

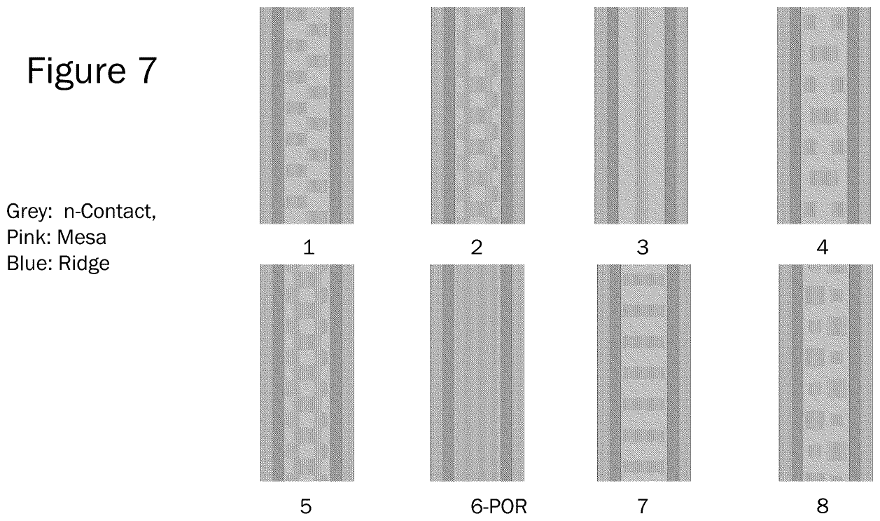

FIG. 5 is a top-view diagram of various patterned contact regions according to an example of the present invention. As shown, a plurality of different contact region patterns is included. For example, the pattern includes replica of an n-chip pattern design, patterns with only longitudinal modulation, patterns with only lateral modulation, and other pattern variations in combination with epitaxial structures for desired and predetermined current injection patterns. FIG. 6 is a top-view diagram of alternative patterned contact regions according to an example of the present invention. FIG. 7 is a top-view diagram of alternative patterned contact regions according to an example of the present invention.

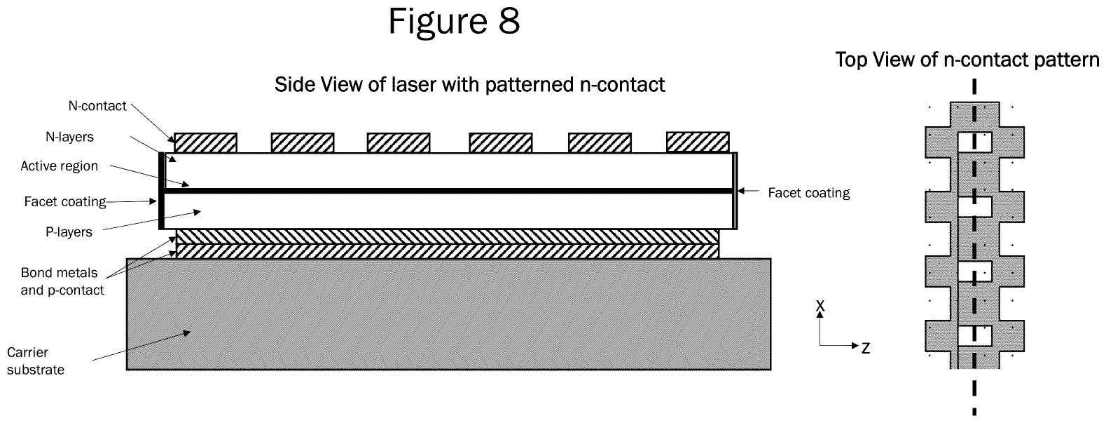

FIG. 8 is a simplified side-view diagram of a laser diode according to an example of the present invention. As shown is a laser device containing a gallium and nitrogen containing material. The device has a carrier substrate member comprising a front side and a back side. The carrier substrate can be silicon, silicon carbide, gallium nitride, sapphire, any other materials, or combinations. The device has a metal bonding material that is free from solder material overlying the front side of the substrate member. The bonding material is configured to bond an overlying transferred material to the front side of the carrier substrate. In a preferred example, the bond is metal to metal using high conductive metal such as gold, silver, or any combination, and others. In an example, the device has a p-type contact region overlying the metal bonding material to form a thermal path and an electrical path to and from the metal bonding material. The device has a p-type gallium and nitrogen containing region overlying the p-type contact region.

In an example, the device has an active region overlying the p-type gallium and nitrogen containing region. The active region comprises a plurality of quantum well regions. The device has an n-type gallium and nitrogen containing region overlying the active region. In an example, the n-type gallium and nitrogen containing region comprises a plurality of sub-regions numbered from 1 to N, where N is an integer of 2 and greater.

In an example, the device has a cavity region configured from a portion of the n-type gallium and nitrogen containing region. The cavity region having a first facet and a second facet. Each of the facets can be etched or cleaved. A coating is applied to each facet. The coating can be reflective or anti-reflective depending upon the application. As shown, the cavity region is formed between the first facet and the second facet and configured to propagate electromagnetic radiation through the cavity region and output a laser beam from one of the first facet or the second facet.

The device has a stripe region configured from an upper surface of the cavity region. In an example, an n-type contact region overlying the stripe region.

The device has a spatial pattern disposed on the n-type contact region and configured with a dimension and a geometry to achieve a predetermined mode quality (“M2”).

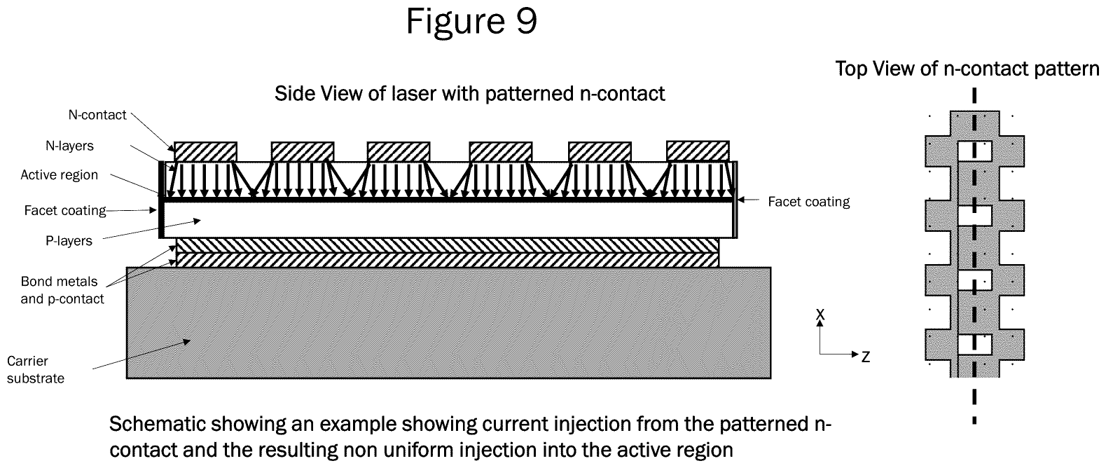

FIG. 9 is a simplified side-view diagram of a laser diode according to an example of the present invention. As shown, current injection from an n-type patterned contact region is illustrated. The n-type patterned contact region is selectively configured to achieve a desired spatial pattern for current injection into the active region. Such current injection allows the laser device to be operable in selected modes.

In other examples, the present invention provides a taped waveguide laser device. In an example, a tapered section can be gain guided or index guided. In an example of a gain guided, the tapered section is designed by an injection area in shape of taper with flared angle close to free diffraction of a single lateral mode from a straight section. In an example, the index change is configured by a change in gain in the tapered section due to injection on taper section. The gain guided taped section leads to low beam divergence at high powers. For the index guided, the taper section is designed by index contrast between a semiconductor and its surroundings in general by a ridge etched waveguide. An angle of the taper is designed to maintain and expand the single lateral mode operation and amplify its power.

In an example, the present techniques take careful consideration of the complex spatial-spectral dynamics in semiconductor laser diodes are necessary, due to the non-linear effects such as mode filamentation, spatial-hole burning, and thermal lensing. At high powers, the non-linear effects can be a challenge. It is possible to reduce or minimize the non-linear effects by reducing the confinement factor of the waveguide, resulting in high beam quality maintained at higher powers. It is also possible to reduce or minimize these effects by counter-acting them with the addition of patterned electrodes on the taper section. By independently controlling the current injection between the straight section and taper section, one can control the output power verses beam quality. Tapered laser diodes result in high power and beam quality laser with a penalty in efficiency due to the add extra loss during feedback between straight section and taper section.

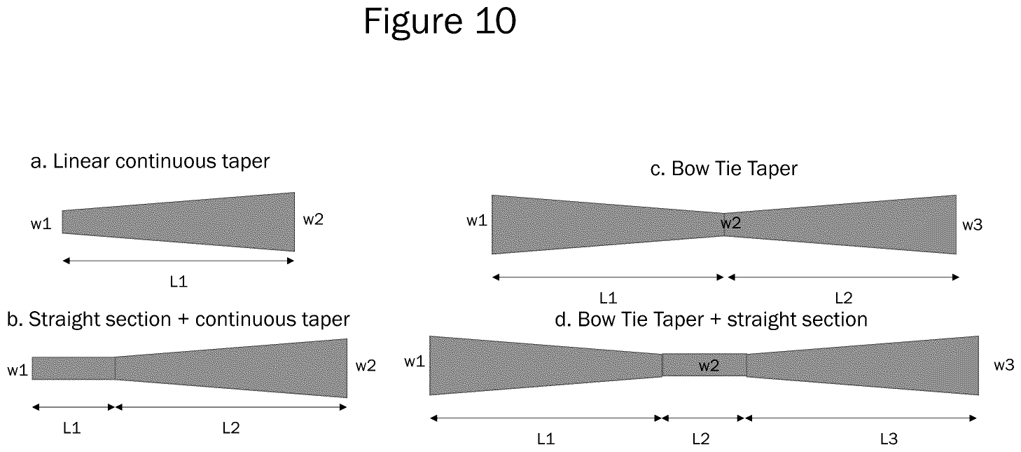

FIG. 10 is a simplified top-view diagram of a tapered waveguide laser device according to an example of the present invention. In an example, the present tapered waveguide laser device is configured for improved mode quality, M². A tapered structure filters higher order lateral modes in the laser to reduce the number of active modes. Proper tapered designs can be used to achieve single lateral mode operation. As shown, several topic view schematics of tapered waveguide laser geometries are illustrated, but not intended to be comprehensive. In an example, the lateral width tapers can be linear tapers as shown below, can be exponential tapers, can be adiabatic tapers, or can be some combination thereof.

Various sizes are also illustrated. In A, w1 can range from about 1 μm to about 10 um, and w2 can range from about 5 μm to about 100 um or greater. L1 can range from 500 μm to 5 mm. In B, w1 can range from about 1 μm to about 10 um, and w2 can range from about 5 μm to about 100 um or greater. L1 can range from 50 μm to about 1 mm and L2 can range from 500 μm to 5 mm. In C, w1 and w3 can range from about 5 μm to about 100 μm, and w2 can range from about 1 um to about 10 um or greater. L1 and L2 can range from 300 μm to about 3 mm. In D, same as C, but L2 can range from about 5 μm to about 500 um. Of course, there can be variations.

In an example, tapered laser diodes (or flared unstable cavity lasers) can be designed to provide high brightness, e.g., high power plus good beam quality. A tapered laser diode includes at least a straight narrow ridge waveguide section providing a single lateral mode combined with a tapered section designed to maintain single lateral mode while amplifying power of the diode.

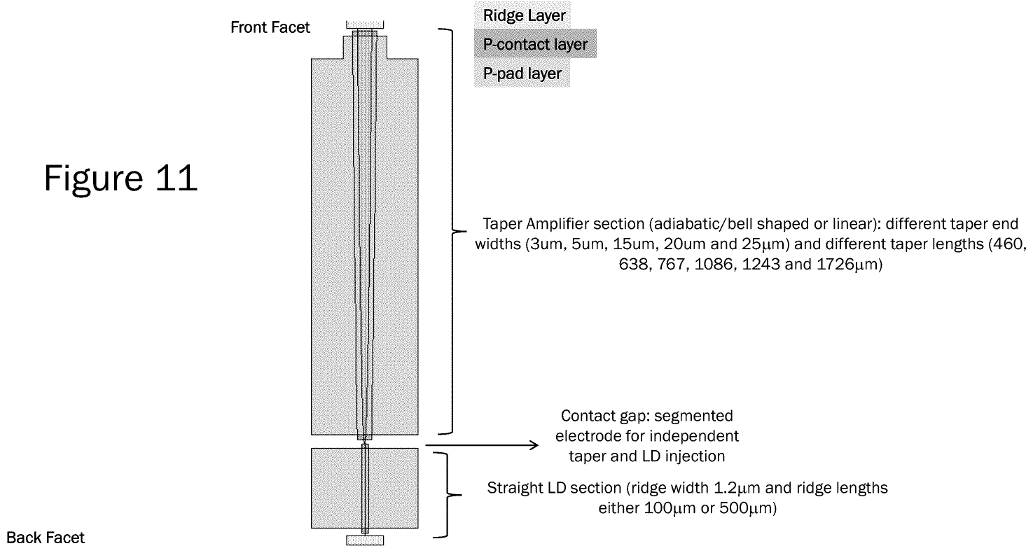

FIG. 11 is a simplified top view diagram of a straight laser diode configured with a tapered waveguide laser diode according to an example of the present invention. In an example, the straight and/or tapered laser diode is configured with patterned contact regions. As shown, a tapered amplifier section (e.g., adiabatic/bell shaped or linear) has various tapered end widths, e.g., 3 um, 5 um, 15 um, 20 μm and 25 μm, and various tapered lengths, e.g., 460, 638, 767, 1086, 1243 and 1726 um. In an example, end widths can be much larger, all the way to 50 um and above, and 100 μm and above. In an example, lengths can range up to 5 um. A contact gap between the tapered amplifier section and the straight laser diode can be a predefined length, e.g., 4 um, to form a segmented electrode for the independent tapered structure and laser diode injection. The gap ranges from about 2 μm to about 20 um, but can be others.

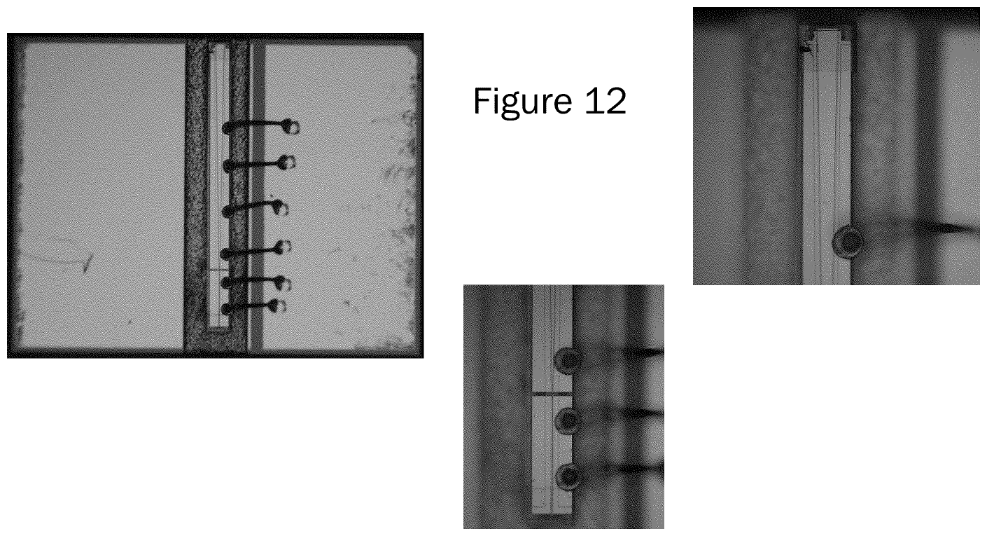

FIG. 12 is a simplified illustration of images of tapered waveguide laser diodes according to an example of the present invention. As shown, top view images include tapered waveguide structure, and overlying patterned contact region, which is configured on n-type material. A plurality of conductors in the form of wires couple the patterned contact region to a bus bar region.

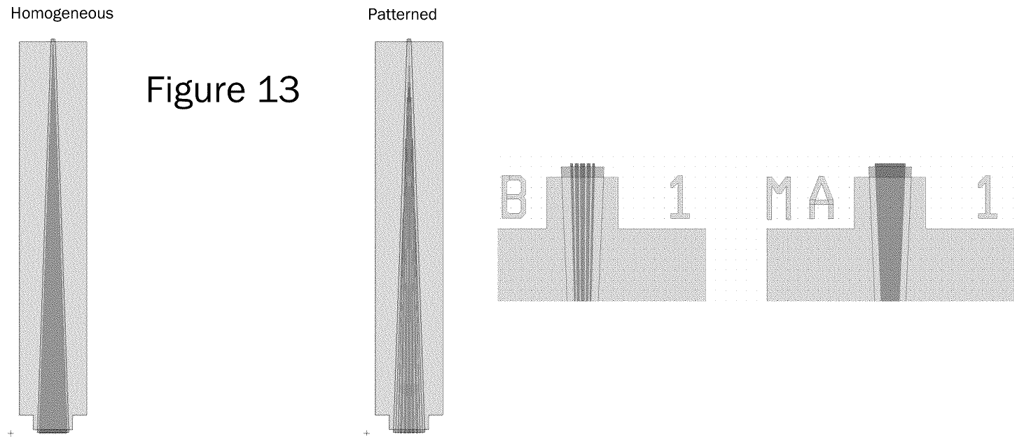

FIG. 13 is a simplified illustration of mask devices for a tapered waveguide laser diode according to an example of the present invention. Various mask devices are shown, including a homogeneous design and a patterned design in examples.

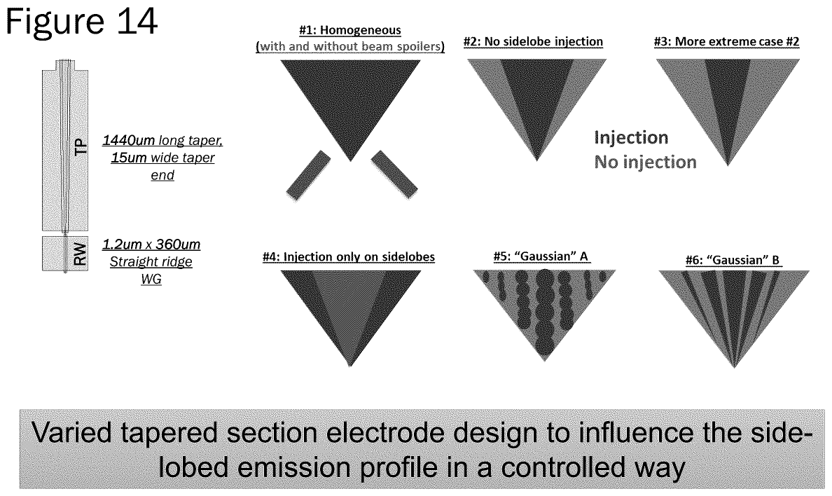

FIG. 14 is a simplified illustration of various patterned contact regions of tapered waveguide laser diodes according to examples of the present invention. A straight waveguide laser diode is configured with a tapered amplifier waveguide illustrated on a left side of the illustration. Shown are various patterned contact regions configured as electrode devices. In an example, a selected pattern is configured to achieve a predetermined side lobe emission pattern in a desired manner. The patterned contact regions configured on a tapered waveguide can be configured with an n-type region overlying an active region of the laser diode to achieve a predetermined current injection pattern into the active region.

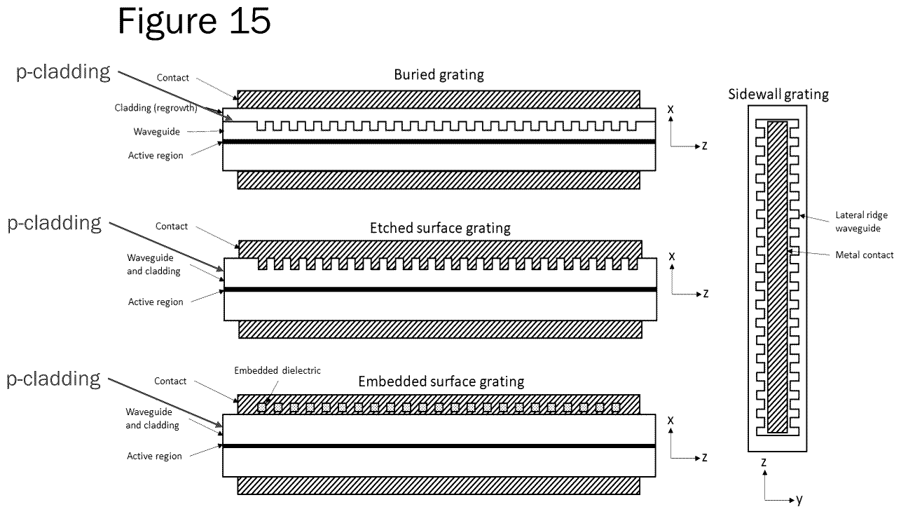

FIG. 15 is a simplified illustration of a distributed feedback laser diode device according to an example of the present invention. As shown, the invention includes a distributed feedback laser diode device. The grating for the distributed feedback can be etched, buried, or embedded, each of which is configured on a laser diode device with an n-type region that is disposed in an upside configuration, while the p-type region is within a vicinity of a carrier substrate.

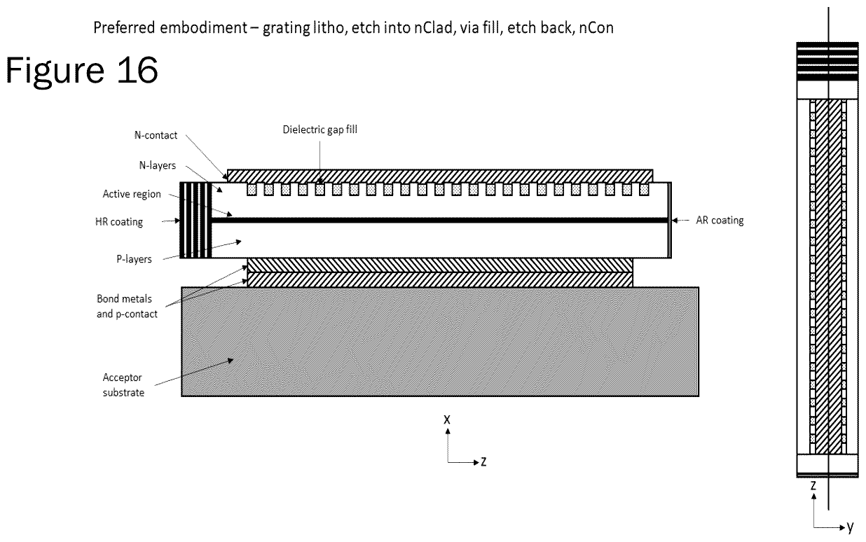

FIG. 16 is a simplified illustration of a distributed feedback laser diode device according to an alternative example of the present invention.

In a preferred example, the distributed feedback laser diode device has patterned n-type contact regions. Preferably, the patterned contact regions are combined with an underlying n-type gallium and nitrogen containing structure to selectively provide current injection into an active region to achieve desired performance for the laser diode device.

As background, multimode semiconductor GaN laser diodes with >4 W output have been available. However, single-lateral-mode GaN lasers that can operate at such power levels have not been realized and are typically limited to below 500 mW. Even further, single frequency GaN lasers at any power are not commercially available. Demand is rapidly accelerating for high-power, compact, reliable single-mode semiconductor lasers for applications including lidar, medical, laser pumping, defense and security, industrial such as welding, cutting, engraving, and 3D printing, Raman spectroscopy, and applications like nuclear fusion. Single-lateral mode lasers offer higher beam quality or M² values, which improve the brightness and efficiency of optical coupling such as fiber coupling. High power single-mode and single-frequency GaN lasers operating in the visible wavelength range with multi-watts, 100s of watts, kilowatts, or higher power with high beam quality can offer many advantages over the relatively low power (<500 mw or <1 W) single-lateral-mode GaN lasers that are commercially available in the market, which do not operate with single frequency.

In the present example, we introduce a monolithic MOPA device or tapered laser device that provides single-lateral mode, or single longitudinal mode for single-frequency operation at high power (>1 W). The output of the high-power single frequency devices can be aggregated to by beam combining in many configurations. In one configuration, the devices are spatially combined, and/or polarization combined, and/or wavelength combined, or some combination thereof. In one example, single-frequency MOPA devices or tapered laser devices are beam combined using a phase locked approach to aggregate power.

In this present invention, we introduce a novel monolithic master oscillator power amplifier (MOPA) in the form of a single-lateral-mode, and optionally, single frequency, seed laser with a tapered amplifier to amplify the emission from the seed laser that can reach single-mode or single-frequency power levels of more than 1 W, more than 2 W, more than 4 W, more than 6 W, or more than 10 W single-longitudinal-mode operation. The MOPA device includes a single lateral mode, narrow waveguide width (1 μm to 3 um), master oscillator or seed laser with an optional Bragg reflector such as distributed feedback laser for single frequency operation. The seed laser can range in length from about 50 μm to about 2 mm. The seed laser is monolithically coupled to a tapered waveguide amplifier region where the waveguide width is increased over predetermined length to greater than 5 um, greater than 15 um, greater that 30 um, greater than 50 μm, or greater than 100 μm. The waveguide length can be longer than 500 um, longer than 1 mm, longer than 1.5 mm, longer than 2 mm, or longer than 3 mm.

In other examples the device is configured as a tapered laser device that can reach single-mode or single-frequency power levels of more than 1 W, more than 2 W, more than 4 W, more than 6 W, or more than 10 W single-longitudinal-mode operation. The tapered laser device includes a single lateral mode, narrow waveguide width (1 μm to 3 um), section with a Bragg reflector and at least one tapered waveguide region where the waveguide width is increased over predetermined length to greater than 5 um, greater than 15 um, greater that 30 um, greater than 50 μm, or greater than 100 μm. The waveguide length can be longer than 500 um, longer than 1 mm, longer than 1.5 mm, longer than 2 mm, or longer than 3 mm.

This invention enables a GaN-based manufacturable, robust, and reliable MOPA or tapered laser with single mode and/or single frequency at these power levels. In some examples the GaN MOPA device or tapered laser device is configured to operate with a single lateral mode. In other examples the GaN MOPA device or tapered laser device is configured to operate with single-longitudinal mode. In other examples the GaN MOPA device or tapered laser device is configured to operate both with single lateral mode and single longitudinal mode to enable a single frequency GaN device. The GaN MOPA or tapered laser device can be configured to operate at a peak emission wavelengths of 395 nm to 450 nm, 450 nm to 500 nm, or 500 nm to 550 nm, or longer than 550 nm. The MOPA or tapered laser is a monolithically integrated photonic device capable of true single-mode output at high power. It includes a master oscillator section consisting of a seed laser with an integrated Bragg reflector and a power amplifier section. The MOPA device or tapered laser device is unique because it is a high-power, single monolithic device, making it compact and low-cost to manufacture in volume. Further details of the MOPA device and related techniques are described throughout the present specification and more particularly below.

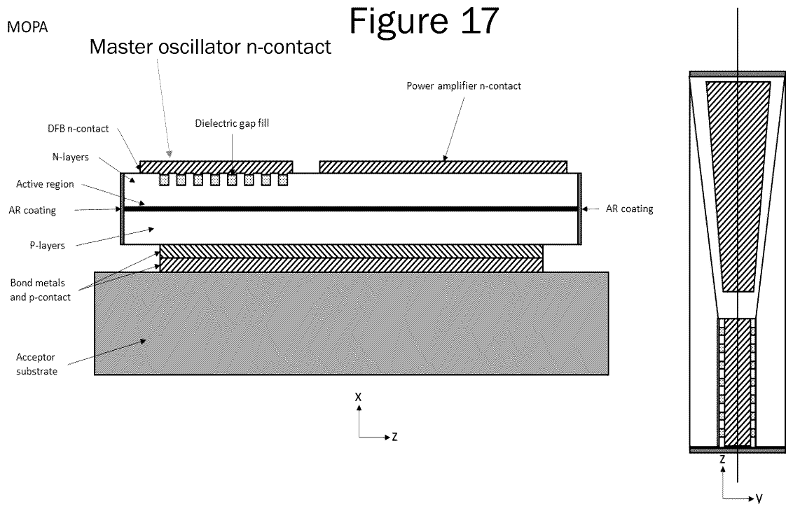

FIG. 17 is a simplified side-view diagram of a MOPA device according to an example of the present invention. As shown, the device has a master oscillator device coupled to an amplifier device, which is configured on a tapered cavity region. The master oscillator device is formed on a cavity with a constant width. Other elements are also shown. A technique for manufacturing the MOPA device can be found in U.S. Patent Application Publication No. US-2022-0344476, commonly assigned, and is hereby incorporated by reference herein.

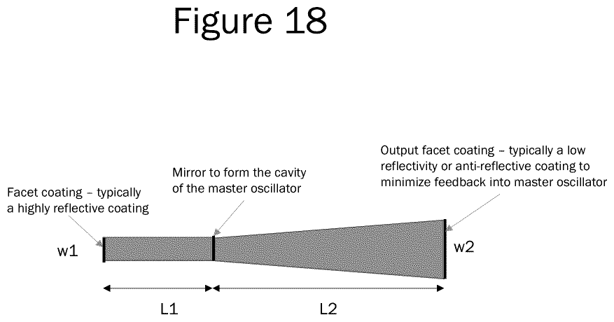

FIG. 18 is a simplified top-view diagram of a MOPA device configured with a tapered amplifier according to an example of the present invention. The MOPA device includes a single lateral mode, narrow waveguide width (1 μm to 3 μm, or more), master oscillator or seed laser with a length of L1. The seed laser can range in length, L1, from about 50 μm to about 3 mm. The seed laser is configured with a cavity that has feedback through end mirrors to form a Fabry Perot resonator or through other types of mirrors. The master oscillator is electrically injected with current through an n-type and a p-type electrode to create gain and achieve lasing. The master oscillator is monolithically coupled to a tapered waveguide amplifier region such that the output from the oscillator is fed into the amplifier region to increase the power level of the output. The amplifier typically has a waveguide width that is increased over predetermined length, L2. The waveguide length, L2, can be longer than 500 um, longer than 1 mm, longer than 1.5 mm, longer than 2 mm, or longer than 3 mm. Over this length the width can increase to greater than 5 um, greater than 15 um, greater that 30 um, greater than 50 μm, or greater than 100 um at the output facet. For higher reliable power levels, the width is increased appropriately. For example, for a reliable continuous wave power of 5 W a width of greater than 40 or 50 um may be desired at the output facet. The amplifier region is electrically biased independent from the master oscillator region. The higher the current injected to the power amplifier the higher the gain and higher the output power. In some configurations of the present example a patterned contact is used in the power amplifier to preserve mode quality.

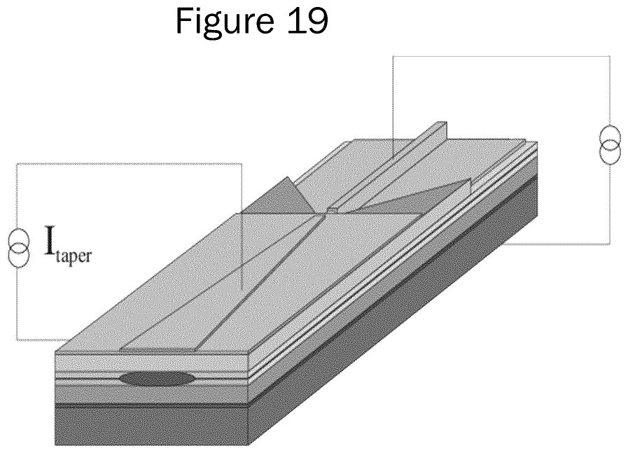

FIG. 19 is a simplified perspective-view diagram of a MOPA device according to an example of the present invention. As shown is an example of a perspective view of a tapered laser diode device. In an example, the waveguide tapered structure is configured with an n-type region side facing up on the device.

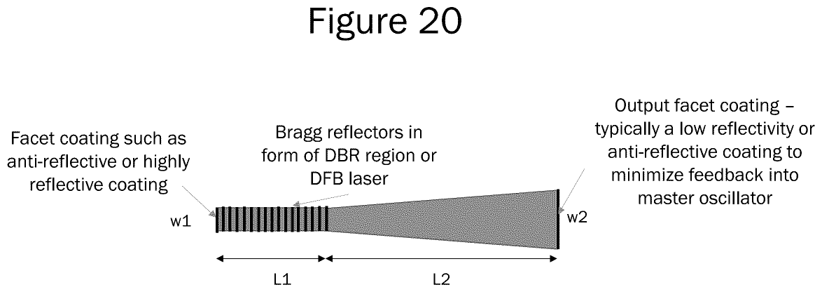

FIG. 20 is a simplified top-view diagram of a MOPA device configured with a single frequency according to an example of the present invention. As shown, the MOPA device includes a single lateral mode, narrow waveguide width (1 μm to 3 μm, or more), master oscillator or seed laser with a length of L1. The seed laser can range in length, L1, from about 50 μm to about 3 mm. The seed laser is configured with a cavity that has feedback through Bragg reflectors such as distributed reflector regions inside the laser cavity and end mirrors or with a distributed feedback (DFB) laser configuration to create a single frequency or single longitudinal mode operation.

In an example, the master oscillator is electrically injected with current through an n-type and a p-type electrode to create gain and achieve lasing. The master oscillator is monolithically coupled to a tapered waveguide amplifier region such that the output from the oscillator is fed into the amplifier region to increase the power level of the output. The amplifier typically has a waveguide width that is increased over predetermined length, L2. The waveguide length, L2, can be longer than 500 um, longer than 1 mm, longer than 1.5 mm, longer than 2 mm, or longer than 3 mm. Over this length the width can increase to greater than 5 um, greater than 15 um, greater that 30 um, greater than 50 μm, or greater than 100 um at the output facet. For higher reliable power levels the width is increased appropriately at the output facet. For example, for a reliable continuous wave power of 5 W a width of greater than 40 or 50 um may be desired. The amplifier region is electrically biased independent from the master oscillator region. The higher the current injected to the power amplifier the higher the gain and higher the output power. In some configurations of the present example a patterned contact is used in the power amplifier to preserve mode quality.

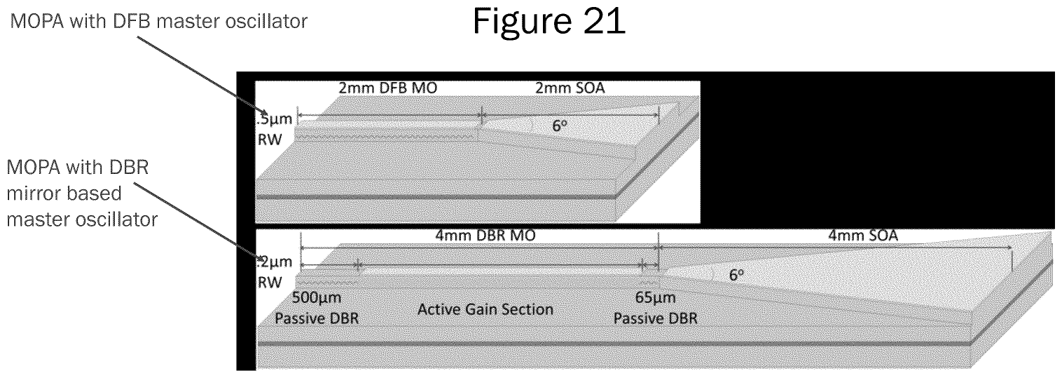

FIG. 21 is a simplified top-view diagram of a MOPA device configured with a distributed feedback reflector and a distributed Bragg reflector according to an example of the present invention. As shown, the MOPA device can have gratings for the distributed feedback reflector or a distributed Bragg reflector.

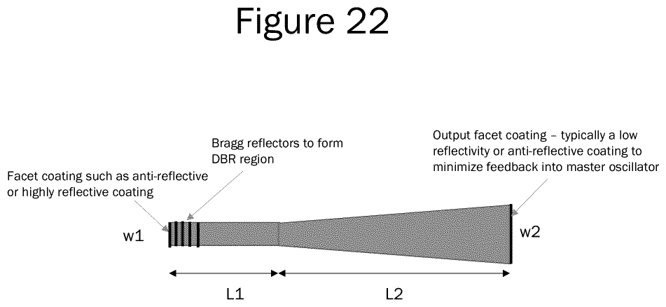

FIG. 22 is a simplified top-view diagram of a single frequency taped laser diode device configured with a distributed feedback reflector according to an example of the present invention. As shown, the tapered laser device includes a single lateral mode, narrow waveguide width (e.g., 1 μm to 3 μm, or more) single mode region with a length, L1, and a tapered waveguide region with a length L2. The narrow waveguide single mode region can range in length, L1, from about 50 μm to about 3 mm and can be configured with a Bragg reflector region such as distributed reflector region to create a single frequency or single longitudinal mode operation. The tapered waveguide region has a waveguide width that is increased over predetermined length, L2. The tapered waveguide length, L2, can be longer than 500 um, longer than 1 mm, longer than 1.5 mm, longer than 2 mm, or longer than 3 mm. Over this length the width can increase to greater than 5 um, greater than 15 um, greater that 30 um, greater than 50 μm, or greater than 100 μm. For higher reliable power levels the width is increased to appropriately levels at the output facet. For example, for a reliable continuous wave power of 5 W a width of greater than 40 or 50 um may be desired.

In an example, the amplifier region is electrically biased independent from the master oscillator region. The higher the current injected to the power amplifier the higher the gain and higher the output power. The tapered laser is electrically injected with current through at least one set of n-type and a p-type electrodes to create gain and achieve lasing. In some preferred examples there can be more than one set of electrodes along the cavity to independently tune the electrical injection and gain along the length of the tapered laser. For example, there may be 2 or more sets of electrodes in the single mode waveguide region and 2 or 3 or 4 or more sets of electrodes along the tapered region. In some examples of the tapered single frequency tapered laser, there are multiple sections with Bragg gratings including Bragg gratings in the tapered waveguide regions. In some examples the Bragg gratings are configured along the entire cavity or along a majority of the cavity. In some configurations of the present example a patterned contact is used in the power amplifier to preserve mode quality.

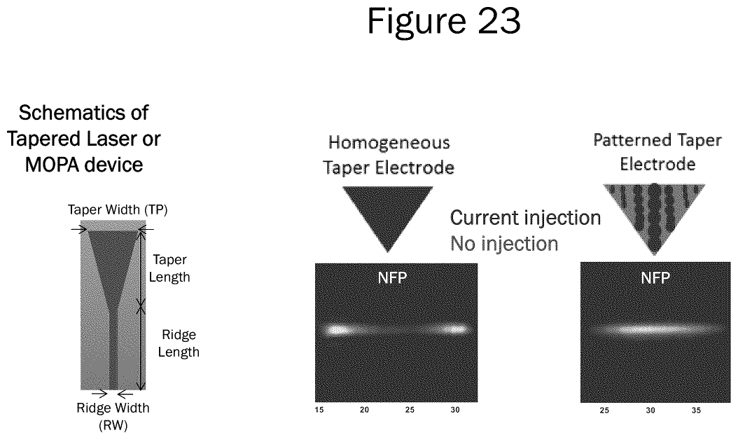

FIG. 23 illustrates a MOPA or taped waveguide laser device configured with various patterned contact regions according to an example of the present invention. As shown, patterned contact regions (e.g., electrodes) are implemented on a taper section, p-side down. Also shown is an Indication that mode profile is more homogeneous with modulation of current/gain in active region due to patterning of the contact regions.

According to the present invention using the gallium nitride transfer technology, arrays of lasers or MOPAs can be configured on “laser bars” wherein N tapered lasers or MOPA are position adjacent to each other on the same chip to form a bar. On the laser bar, the number of emitters, N, can range from 2 to 100 and they can be spaced by about 25 um to about 500 um, but of course there could be others. The individual emitters can be electrically connected in series or connected in parallel, and in some examples, there can be a series parallel configuration where certain groups of lasers are connected in series, and then these groups are connected in parallel with other series connected groups. By designing the electrical connections different current and voltage operating regimes can be achieved. For example, by connecting high power GaN tapered lasers in parallel, the drive electronics would need to source high current levels of about 5 to 30 amperes and low voltages of about 1 to 4 volts. However, if the 5 emitters were connected in series, the drive current maybe 1 to 6 amperes with a drive voltage of 12 to 25V. Further details of techniques for forming arrays of laser bars can be found throughout the present specification and more particularly below.

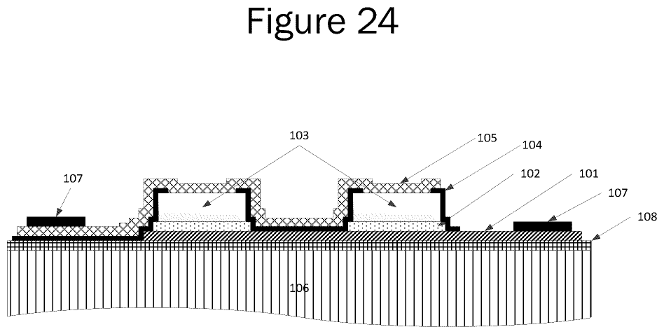

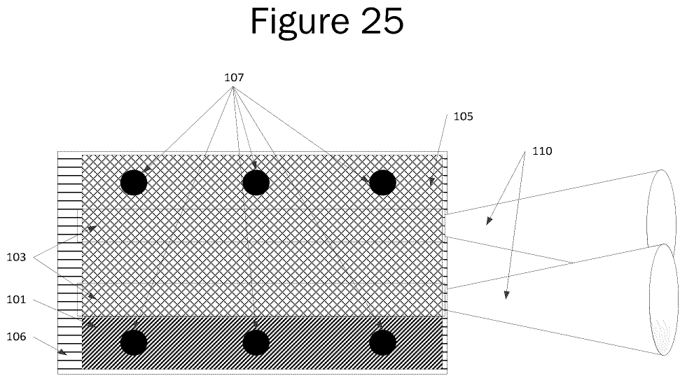

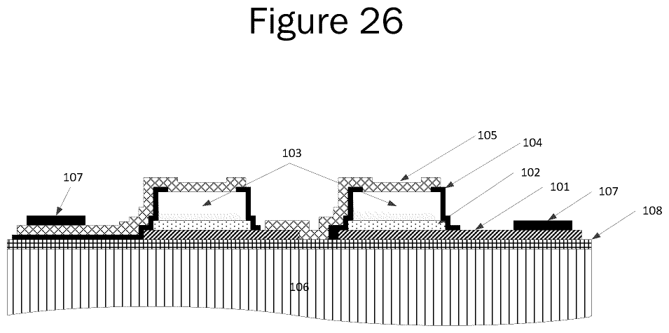

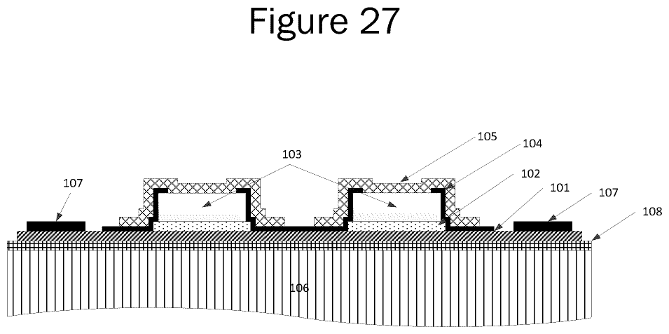

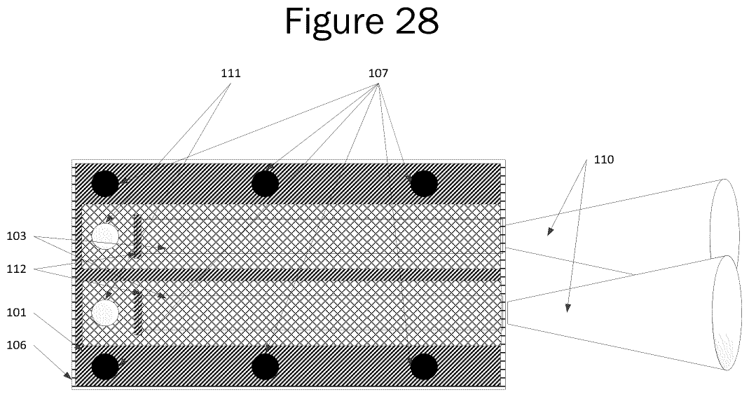

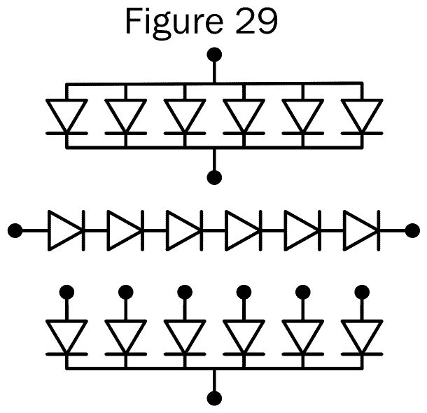

FIGS. 24 to 29 illustrate various view of an array of lasers or MOPAs that are configured as laser bars. As shown, FIG. 24 is a schematic cross-section of one embodiment of a multiple emitter laser device according to this invention wherein the laser stripes are electrically connected in parallel. FIG. 25 shows a top-view schematic of the embodiment of a multiple emitter laser device shown in FIG. 24 according to this invention. FIG. 26 is a schematic cross-section of an embodiment of a multiple emitter laser device according to this invention wherein the laser stripes are electrically connected in series. FIG. 27 is a schematic cross-section of an embodiment of a multiple emitter laser device according to this invention wherein the laser stripes are electrically individually addressable. FIG. 28 shows a top-view schematic of the embodiment of a multiple emitter laser device shown in FIG. 26 according to this invention. FIG. 29 shows schematic of electrical equivalent circuits for the three embodiments of multiple emitter laser device shown in FIG. 25, FIG. 26, and FIG. 27 according to this invention. Further details on such laser bars including a method of manufacture can be found in U.S. Patent Application Publication No. US-2021-0344164, commonly assigned and hereby incorporated by reference in its entirety herein.

In an example, the present laser devices can be configured in a system for high power applications. As an example, single emitter GaN lasers can generate greater than 3 W, greater than 5 W, and greater than 8 W, but in many applications such as industrial welding, cutting, or 3D printing, much higher total power is desired. In these applications various approaches are used for beam combining. The laser beams from separate discrete laser beams can be combined, and or the N beams from a laser bar with N emitters are combined. For example, if 20 5 W lasers are beam combined, a total of 100 W can be achieved in the combined beam. In certain applications, it is important that brightness is maximized by combining the laser beams into a final beam that has a minimized diameter or size or into a fiber with a minimized fiber core diameter such as 50 um, 100 um, 200 um, 400 μm or larger fiber core diameter.

As noted, beam combining the output of laser bars is efficient because the emitters are spatially arranged with a very tight and compact tolerance based on the lithographic process steps that are used to define the laser stripes. This enables more efficient collimation of the laser beams prior to beam combination since optical elements such as micro lens arrays can be aligned to all the emitters in the laser bar in one alignment sequence whereas if the beams of individual lasers are being combined, the alignment sequence must be performed for each emitter. That is, for a laser bar that has 20 emitters, the 20 emitters can be optically collimated much more efficiently than collimating 20 separate discrete lasers. Since this optical collimation process typically requires an active alignment process, it can be time consuming and contribute substantial overall cost to the process.

In this invention, tapered laser bars or MOPA device bars are optically collimated and beam combined using a system approach. In a preferred example of the present invention, single frequency MOPA devices or tapered lasers are configured in a bar with N emitters, optically collimated, and beam combined using one or more beam combining methods.

There are several approaches that can be used to combine the optical output laser beams from the tapered laser devices or MOPA devices, wherein beam combining can be performed on individual discrete tapered lasers or MOPA devices and or from tapered laser bars or MOPA device bars, or some combination thereof.

In a first beam combining method, the output laser beams from the tapered lasers or MOPA devices according to the present invention are spatially combined into a single collimated beam or into a waveguide device such as an optical fiber. Spatial beam combining, sometimes called side by side combining, deploys an optical pathway configuration wherein the output from 2 or more laser devices are collimated in the slow and or fast axis directions, and then the 2 or more collimated laser beams are configured with an optical pathway that results in adjacent parallel propagation. This is often done with a series of optics such as fast axis collimating lenses, slow axis collimating lenses, micro lens arrays, spherical lenses, turning mirrors, dichroic mirrors, and some sort of spatial difference between each laser device such as the mounting height, or z-alignment. This spatial difference dictates the relative position of each laser beam in the resulting beam of collimated co-parallel beams.

In a second beam combining method, the output laser beams from the tapered lasers or MOPA devices according to the present invention are polarization combined to form a polarization combined output beam.

In a third beam combining method, the output laser beams from the tapered lasers or MOPA devices according to the present invention are spectrally combined to form a spectrally combined output beam.

As used herein, the terms “first” “second” “third” or other numerical values do not imply any order, but can be interpreted broadly to differentiate each technique. Further details of the present techniques can be found in reference to the drawings below.

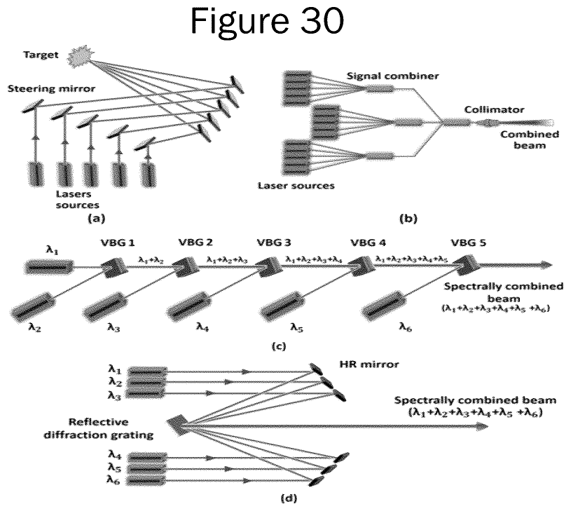

FIG. 30 illustrates schematic representation of four main methods of incoherent beam combining according to an example of the present invention. The methods include (a) spatial beam combining, side-by-side beam combining, (b) beam combining using all-fiber passive signal components, (c) spectral beam combining, SBC with volume Bragg gratings (VBG) as a wavelength-dependent transmission element, and (d) SBC with reflection diffraction grating as a dispersive optical element according to examples of the present invention. See, https://www.mdpi.com/2304-6232/8/12/566.

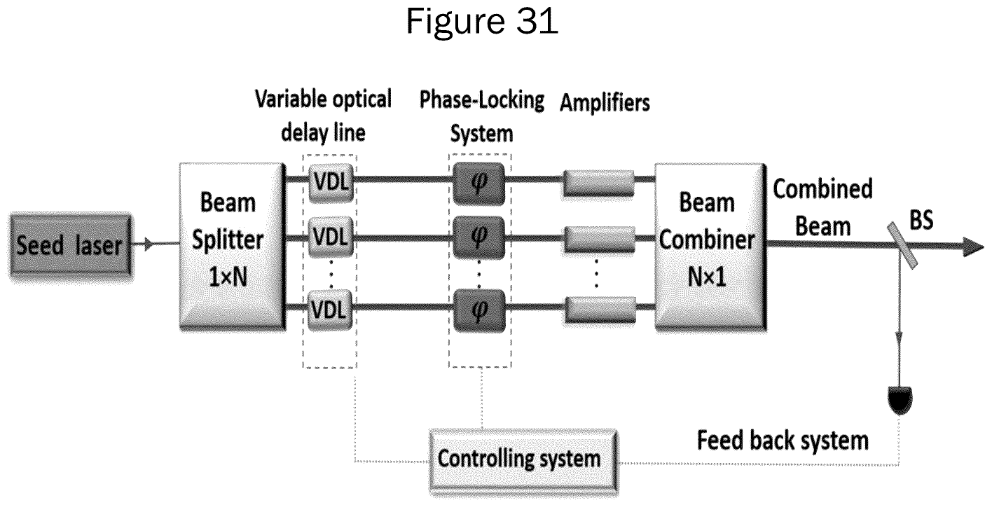

FIG. 31 is a simplified general schematic illustration of coherent beam combining (CBC) according to an example of the present invention. The CBC systems typically involve five principal parts: (i) the geometry of splitting/combining, (ii) laser sources and amplifying section, (iii) phase-locking system, (iv) optical path difference (OPD) control, and (v) number of channels. All of them will be discussed in detail in this section with the emphasis both on the concept and operation principles. See, https://www.mdpi.com/2304-6732/8/12/566.

In some embodiments according to the present invention, a high-power laser system is formed by amplifying and aggregating the output of N high power single-mode or single-frequency GaN-based laser diodes. The output optical signal from the GaN based laser diode can be a continuous wave signal, a pulsed signal, or a combination thereof. One or more laser beam combination techniques can be implemented to aggregate or combine the laser beams and the combined laser beams can be further amplified. Incoherent beam combinations techniques, such as spectral beam combining, polarization beam combining, and spatial beam combining, can be implemented individually or in combination. In some embodiments, coherent beam combining is used to form the high-power laser system. In coherent beam combining, a single beam can be obtained with correspondingly higher power and with substantially preserved beam quality for increased radiance or brightness. Additionally, coherent combining can preserve spectral bandwidth. Combining would preferably occur to increase intensity of the beam without causing destructive interference between a pair of beams.

Spectral beam combining (or wavelength beam combining) is a technique to scale the total beam power by combining several high-power laser beams to obtain a single beam with correspondingly higher power and with a preserved beam quality for increased brightness. In spectral beam combining, several beams with non-overlapping optical spectra may be combined within some kind of wavelength-sensitive beam combiner such as prisms and/or diffraction gratings, which can deflect incident beams according to their wavelengths so that subsequently they all propagate in the same direction. Other approaches rely on optical components with wavelength-dependent transmissions, such as dichroic mirrors or volume Bragg gratings. In some approaches, the laser emitters are independently tuned to a particular wavelength, and their outputs are aligned to reach the beam combiner at the corresponding angle. In some embodiments, each emitter can automatically adjust its wavelength according to its spatial position. This principle is suitable to laser diodes in the form of diode arrays. Thermal effects of the wavelength-sensitive beam combiners may be considered in the design of the high-power laser system. For transmission gratings, thermal effects may be more severe, whereas reflection gratings can work at power levels of at least 100 kW because they absorb less power and can be cooled.

In polarization beam combining two laser beams with linearly polarized light are combined. In one example, the output of one laser diode that is vertically polarized and another laser diode that is horizontally polarized are provided to a thin-film polarizer. In this configuration, one of the beams is reflected and the other is transmitted such that both beams then propagate in the same direction to form an unpolarized beam having the combined optical power and nearly double the brightness of the input beams.

Coherent beam combining can be classified into categories including side-by-side combining and filled-aperture. Side-by-side combining (tiled aperture) techniques may use a kind of phased array, leading to a larger beam size but reduced divergence. Filled-aperture techniques, where several beams are combined into a single beam with the same beam size and divergence, may use, for example, a grating splitter. In any case, mutual coherence of the combined beams is important. As a simplified example of side-by-side combining, four beams with flat-top intensity profiles of rectangular cross-section and flat phase profiles may be arranged to obtain a single beam with just two times the dimensions, or four times the area, and of course four times the power. If the beams are all mutually coherent, and the relative phases are properly adjusted to obtain essentially plane wavefronts over the whole cross-section, the resulting beam has a beam divergence that is only half that of the individual beams. As a result the beam quality is preserved, and the brightness can be four times that of the single beams.

In addition to phase coherence, the combined beams can also have a stable linear polarization with reasonable amplitude fluctuations. There are several methods for obtaining mutual coherence. Mutually coherent single-frequency signals can be generated by splitting the output of a low-power single-frequency laser and amplifying the resulting beams such as in high-power fiber amplifiers. Since the amplifiers may introduce amplifier noise, particularly in the form of low-frequency phase disturbances, an active feedback stabilization scheme may be included. The resulting phase-coherent beams can then be combined either at multiple beam splitters or with a tiled-aperture approach. The latter may be more convenient for a larger number of beams. Such techniques may be applied particularly to arrays of fiber amplifiers, laser diodes, and/or ridge waveguide amplifiers.

Alternatively, the phases of multiple high-power lasers can be synchronized by optical coupling. One approach is coupling via evanescent waves (leaky-wave coupling) with the goal of exciting a suitable supermode of the structure that exhibits a high beam quality. This technique may be applied particularly to laser diode arrays containing multiple active waveguides on one chip, where coupling can be obtained simply by placing the waveguides sufficiently closely. A challenge is to obtain both tight coupling with phases that are equal rather than opposite at the outputs of the waveguides. This can be avoided with common-resonator techniques where the beams are fully combined at the output coupler but split within the resonator to be amplified in different gain elements.

For certain optical frequencies, there are supermodes where the reflections from the different sub-resonators add in-phase at the output coupler. If such supermodes lie within the gain bandwidth, lasing may occur only on those, resulting in efficient coherent beam combination. This method may be called self-organizing phase synchronization. It does not require interferometric stabilization of the optical path lengths and may be particularly suitable for fiber lasers. There are also schemes where phase synchronization is achieved using a nonlinear interaction such as stimulated Brillouin or Raman scattering.

Passive beam combining techniques can be deployed where the input lasers automatically obtain mutually coherent oscillation even though they are not single-frequency lasers. However, single-frequency operation is typically required for actively stabilized laser arrays.

Coherent beam combining can also be achieved with non-monochromatic input beams as long as they are mutually coherent. For example, ultrashort pulses having a broad optical spectrum can be coherently combined if the path lengths are matched such that the temporal peaks of the contributions of all input beams to the output occur at the same time. The broader the optical bandwidth the more important is delay matching.

A challenge with coherent beam combining is obtaining phase coherence at high power levels in a stable manner. Another challenge is the need to match wavefronts and polarization directions.

The high-power laser systems according to the present invention are configured with one or more high power beam combining techniques as described above. The N laser beams that are combined can be amplified laser beams that have been amplified by one or more amplifiers such as semiconductor optical amplifiers (SOA), fiber amplifiers, or other types of amplifiers. In an embodiment, a high power single mode or single frequency tapered laser or MOPA device is configured as the source laser for one or more of the N laser beams to be combined. The beams originating from the source lasers may be fed through subsequent amplifiers such as one or more GaN based SOAs. The SOAs can be carefully designed to increase the saturation power or saturation energy such as low optical confinement factor SOAs or gain clamped SOAs. By reducing the optical confinement factor, amplified spontaneous emission (ASE) is suppressed for improvements to the saturation characteristics of the SOA. The suppression of ASE is beneficial for the efficient amplification of optical pulses since a high ASE intensity leads to a reduction in excited carriers in the conduction/valence bands through the stimulated emission process. In addition to the confinement factor, the SOA should have an optimized design including the gain characteristics, active region design, waveguide width, waveguide length, series resistance, propagation loss, and more.

In some embodiments, special types of laser diode sources, such as slab-coupled optical waveguide lasers (SCOWL), may be used with carefully designed waveguide and active region layers to achieve low confinement and low optical loss with high output powers of 1 W to 1 kW or more.

In some embodiments, one or more SOAs are included within the amplification stages of the high-power laser system. In addition to noise level and absolute gain, the saturation power of the SOA is important. In order to maximize the saturation power, the waveguide and active region of the SOA must have a large cross-section for the optical mode so that photons are spread out for a given power. Put another way, the optical confinement factor in the gain medium or quantum wells can be minimized. A small differential gain with a minimized gain medium (e.g., a quantum well) having a small cross-section will support higher saturation power. Additionally, a fast carrier lifetime, for the resupply of carriers to the gain medium, may be desirable. To achieve such properties, careful waveguide and active region design must be used. For example, the number of quantum wells can be reduced to 1 or 2, the quantum wells can be made thin such as 1 to 10 nm or 10 to 25 nm, the optical waveguide can be made very thick, and the quantum wells can be positioned with respect to the waveguide to minimize the optical confinement factor. In one example, a slab coupled optical waveguide amplifier (SCOWA) may be included in one or more of the amplification stages of the high power laser system.

In some embodiments, the high power GaN-based laser diodes are configured as very high-peak-power optical pulse sources. These high-power pulses may be achieved, for example, with gain switching, self-pulsation, mode-locking, and other techniques. The output from the single-mode or single-frequency high power tapered lasers or MOPA devices can be fed through separate GaN-based SOA devices to amplify optical pulses, fiber amplifiers, other types of amplifiers, multi-stage amplifiers, or combinations of amplifiers to amplify the pulses generated by the GaN-based based laser diode such as a mode-locked laser diode (MLLD).

Mode locking is a technique by which a laser can be made to produce pulses of light of extremely short duration, on the order of nanoseconds, picoseconds, or femtoseconds. These pulses can be generated by active mode locking, passive mode locking, fundamental mode locking, harmonic mode locking, self-starting mode locking, additive-pulse mode locking, Kerr lens mode locking, hard/soft aperture mode locking, soliton mode locking, nonlinear mirror mode locking, or regenerative mode locking. In a mode locked laser, one or more pulses circulate in the laser resonator, where each time a pulse hits the output coupler an output pulse is emitted thus forming a regular pulse train. The pulse repetition rate is the inverse of the round-trip time in the laser resonator or an integer multiple of it in the case of harmonic mode locking.

Typically, the pulse duration is between 30 fs and 30 ps and in most cases is orders of magnitude shorter than the pulse spacing. Therefore, the peak power of a mode-locked laser can be orders of magnitude higher than the average power. Mode locking is achieved by using a mode locking device within the laser resonator cavity that can be either an active element such as an optical modulator or a nonlinear passive element such as a saturable absorber. In a steady state of a mode-locked laser, the pulse parameters (pulse energy, pulse duration, chirp, spectral bandwidth, etc.) are all unchanged after each completed round trip such that the various effects influencing the circulating pulse (e.g. laser gain and propagation losses, nonlinearities and chromatic dispersion) must be in a balance. Active mode locking requires the periodic modulation of the resonator losses or alternatively of the round-trip phase change using a modulator such as an acousto-optic modulator, electro-optic modulator, Mach-Zehnder integrated-optic modulator, or a semiconductor electro-absorption modulator. In passive mode locking with a saturable absorber, much shorter (femtosecond) pulses are achieved because a saturable absorber can modulate the resonator losses much faster than an electronic modulator. In this configuration, the shorter the pulse becomes the faster the loss modulation. Hybrid mode locking can be achieved when active and passive mode locking are simultaneously applied. Such hybrid mode-locked lasers combine some key advantages, such as an externally controlled pulse repetition rate, relatively short pulses, and robust initiation of the mode-locked operation.

Conventional GaN-based mode locked laser diodes in MOPA structures have been shown to achieve 300 W. With the laser structure according to the present invention, much higher output powers can be achieved.

Very high-power laser systems may be achieved using the beam combining and laser operation techniques described above when applied to the novel GaN based laser and MOPA structures according to the present invention. The very high output power can be achieved in a continuous wave output mode or a pulsed output mode. In one example of a continuous wave high power laser system, 100 single frequency MOPA devices or taper laser devices output about 1 W to about 10 W of optical power with a wavelength in the 380 nm to 540 nm range. The output of each of these lasers is then fed through a first stage amplifier such as an SOA or fiber amplifier for 10 dB of gain to achieve an output of 10 W to 100 W in each beam. These beams are then amplified in a second stage amplifier with 10 dB of gain to achieve an output of 100 W to 1 kW in each beam. The 100 single mode or single frequency beams with 100 W to 1 kW are then combined using coherent beam combining to achieve a single beam with 10 kW to 100 kW. According to the present invention, multiple of these coherently combined laser units can be combined using spectral beam combining. In one example, 20 of these coherently combined laser units with 10 kW to 100 KW operating at different wavelengths in the range of 380 nm to 480 nm are combined using spectral beam combining to achieve a laser beam with about 200 kW to 2 MW. In one embodiment, two of these laser units with coherent beam combining and spectral beam combining can be further combined using polarization beam combining to achieve a system with 400 kW to 4 MW of continuous wave output power in the spectral range of 380 nm to 480 nm. In some embodiments, spatial beam combining can be applied to spatially beam combine multiple beams such as 20 beams to achieve a system outputting a laser beam with about 8 MW to 80 MW of power. This laser beam could then be further amplified to achieve even higher output powers. Of course this is just one example of combining various amplification and beam combining techniques of a continuous wave laser beam. In light of the embodiments disclosed herein, there could be many others including using different amplification techniques and/or using different numbers of amplification stages, including using amplification stages between different beam combining techniques and changing the order or the type of beam combining techniques.

In another example embodiment, an ultra-high-power pulsed laser beam may be achieved. In one example of a pulsed wave high power laser system, 100 single frequency mode locked laser diode devices such as a MOPA or tapered laser device can output a peak power of about 100 W to about 1 kW of pulsed peak optical power with a wavelength in the 380 nm to 540 nm range. The output of each of these lasers may be fed through a first stage amplifier such as an SOA or fiber amplifier for 10 dB of gain to achieve a peak pulsed output power of 1 kW to 10 kW in each beam. These beams are then amplified in a second stage amplifier with 10 dB of gain to achieve an output of 10 kW to 100 kW peak power in each beam. The 100 single mode or single frequency beams with 10 kW to 100 KW may be combined using coherent beam combining to achieve a single beam with 1 MW to 10 MW of pulsed peak output power. According to the present invention, multiple of these coherently combined laser units can be combined using spectral beam combining. In one example, 20 of these coherently combined laser units with 1 MW to 10 MW operating at different wavelengths in the range of 380 nm to 480 nm are combined using spectral beam combining to achieve a laser beam with about 20 MW to 200 MW. In one embodiment, two of these laser units with coherent beam combining and spectral beam combining can be combined using polarization beam combining to achieve a system with 40 MW to 400 MW of pulsed peak output power in the spectral range of 380 nm to 480 nm. In some embodiments, spatial beam combining can be applied to spatially beam combine multiple beams such as 20 beams to achieve a system outputting a laser beam with about 800 MW to 8 GW of pulsed peak power. This laser beam could then be further amplified to achieve even higher output powers. In light of the embodiments disclosed herein, there could be many others including using different amplification techniques and/or using different numbers of amplification stages, including using amplification stages between different beam combining techniques and changing the order or the type of beam combining techniques.

In some examples, amplifiers with higher gain or systems with more stages of amplification can be implemented to achieve higher pulsed peak output power. For example, peak powers of 10 or 100 GW can be achieved, or peak powers of 1 to 100 terrawatts (TW) can be achieved. In some examples, multiple laser systems generating such high peak powers can be combined together. As an example 100 to 1000 of these laser systems can be combined to direct 100 to 1000 times the power at a target. If 100 10 GW or 1 TW laser systems were combined, a total power at the target could be 1 TW to 100 TW.

In a pulsed laser system, the repetition rate, pulse width, and total energy in each pulse are important operating characteristics that are carefully selected and achieved through system design. The pulsed laser source can be designed and configured to operate with a repetition rate of 1 KHz to about 1 THz, or about 1 MHz to about 100 MHz, or about 100 MHz to about 10 GHz, or about 10 GHz to about 1 THz, or about 1 THz to about 100 THz. This pulse width can range from about 1 ns to about 1 fs, or about 10 micro second to about 100 ns, or about 100 ns to about 10 ps, or about 10 ps to about 100 ps, or about 100 ps to about 10 fs. The total energy in the output beam pulse can be about 1 micro joule to about 10 joules, or about 1 micro joule to about 1 millijoule, or about 1 millijoule to about 100 millijoule, or about 100 millijoule to about 1 joule, or about 1 joule to about 100 joules.

In some embodiments, special cavity designs are included to establish a predetermined pulse width and repetition rate based on the system requirements. For example, the cavity length and index of refraction profile can be carefully designed. Additional active and/or passive elements can be inserted into the cavity to modify the pulse width or repetition rate, and other approaches of mode locking can be established.

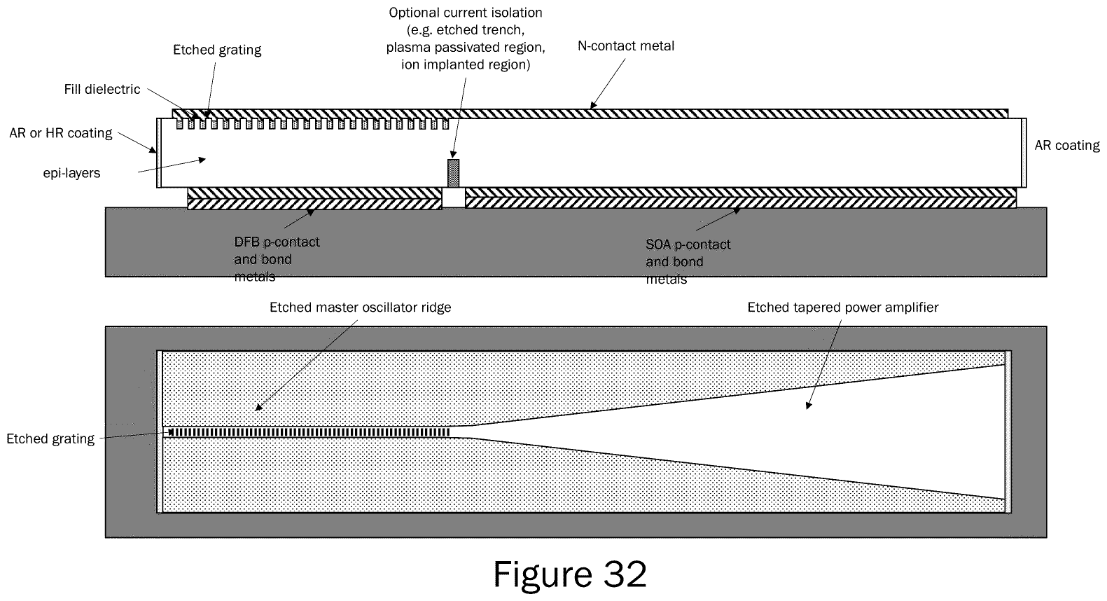

FIG. 32 includes simplified top-view and cross-sectional diagrams of a MOPA or laser diode device according to an example of the present invention. The device in this example includes an etched grating region and a tapered amplifier region. As with other embodiments described and/or shown herein, the tapered sections may be adiabatic/bell shaped or linear.

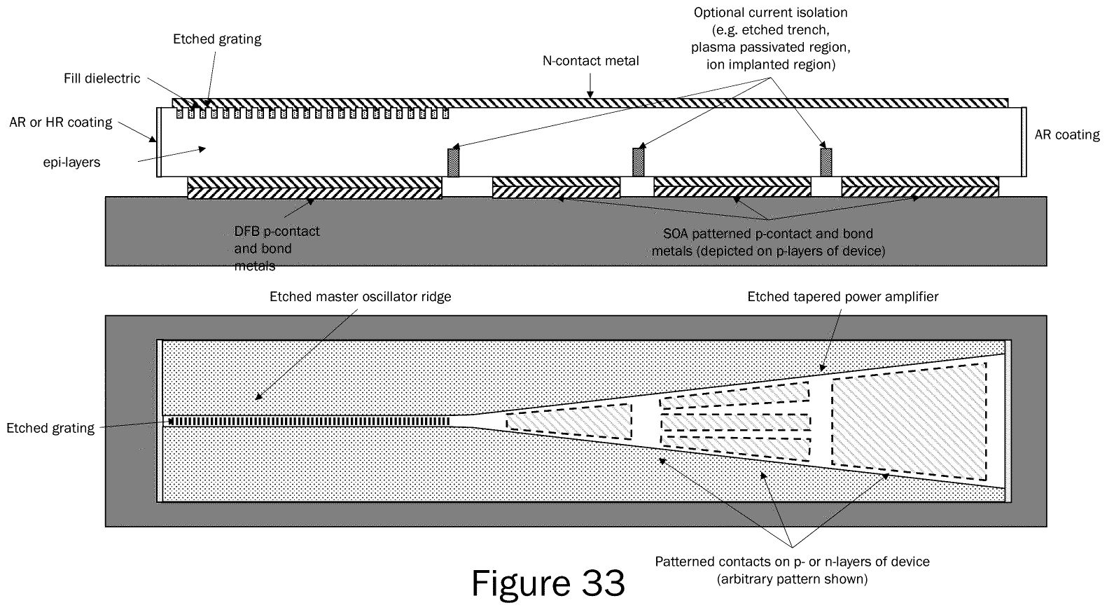

FIG. 33 includes simplified top-view and cross-sectional diagrams of a MOPA or laser diode device according to an example of the present invention. The device in this example includes an etched grating region and a tapered amplifier region. The etched grating region and/or a tapered amplifier region may be configured with patterned contacts. One or more current isolation features may be provided between the etched grating region and the tapered amplifier region. The current isolations features may be provided, for example, by an etched trench, a plasma passivated region, an ion implanted region, or the like.

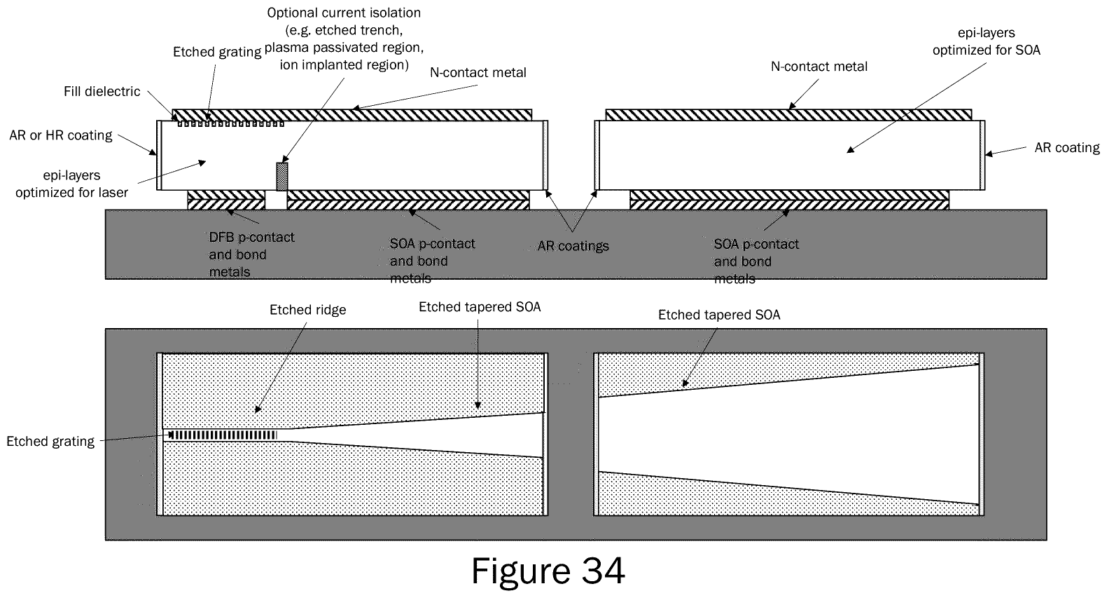

FIG. 34 includes simplified top-view and cross-sectional diagrams of a continuous mesa single-frequency MOPA or laser diode device with a separate mesa amplifier according to an example of the present invention. The MOPA or laser diode device and/or the separate mesa amplifier may be configured with patterned contacts. This example illustrates a single chip arrangement where one or both sides of the separate mesa amplifier may be AR coated. The separate mesa amplifier may have a different epi design, with modifications such as a lower confinement factor. A current isolation feature between the etched grating and the tapered region of the MOPA or laser diode device may be provided, for example, by an etched trench, a plasma passivated region, an ion implanted region, or the like. A gap is provided in this example between the MOPA or laser diode device and the separate mesa amplifier and may form a segmented electrode for independent injection.

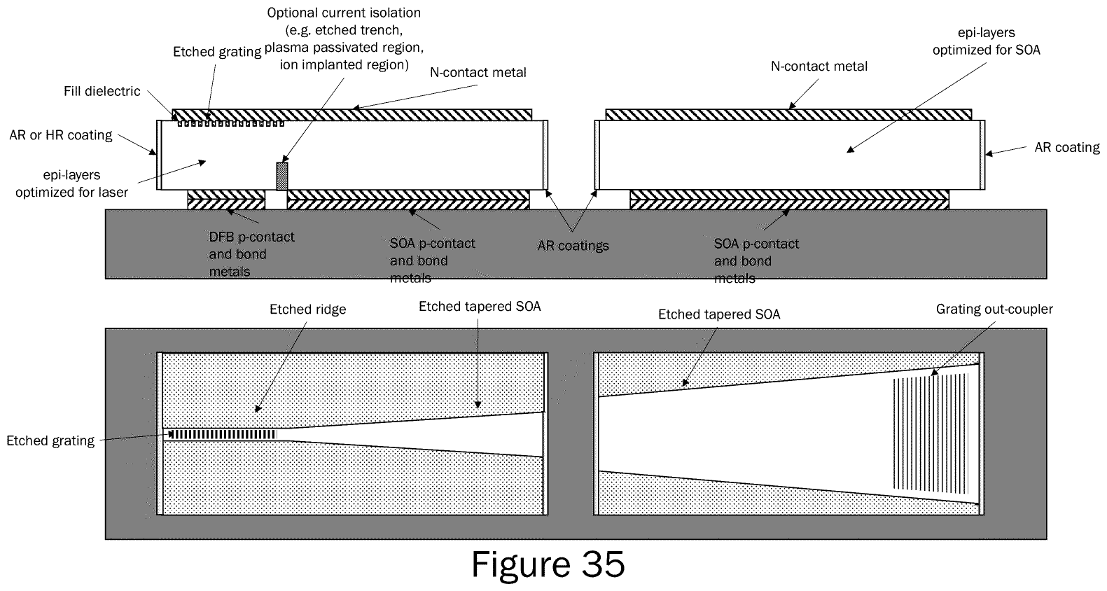

FIG. 35 includes simplified top-view and cross-sectional diagrams of a continuous mesa single-frequency MOPA or laser diode device with a separate mesa amplifier according to an example of the present invention. This example is similar to that of FIG. 34 with a grating out-coupler at an output of the separate mesa amplifier.

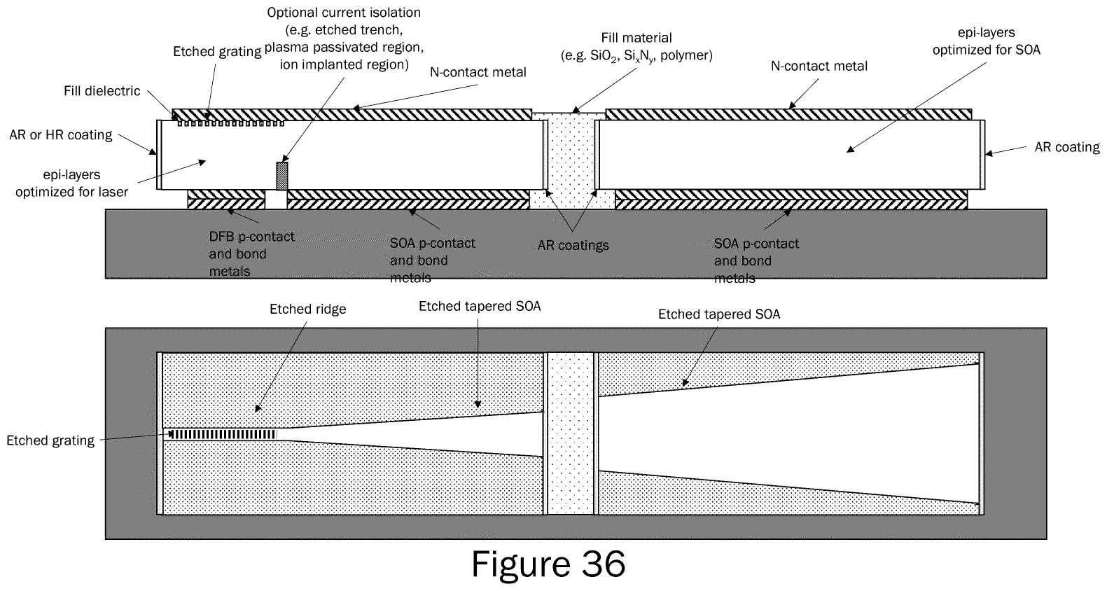

FIG. 36 includes simplified top-view and cross-sectional diagrams of a continuous mesa single-frequency MOPA or laser diode device with a separate mesa amplifier according to an example of the present invention. This example is similar to that of FIG. 34 with a fill material between the mesas to improve coupling efficiency.

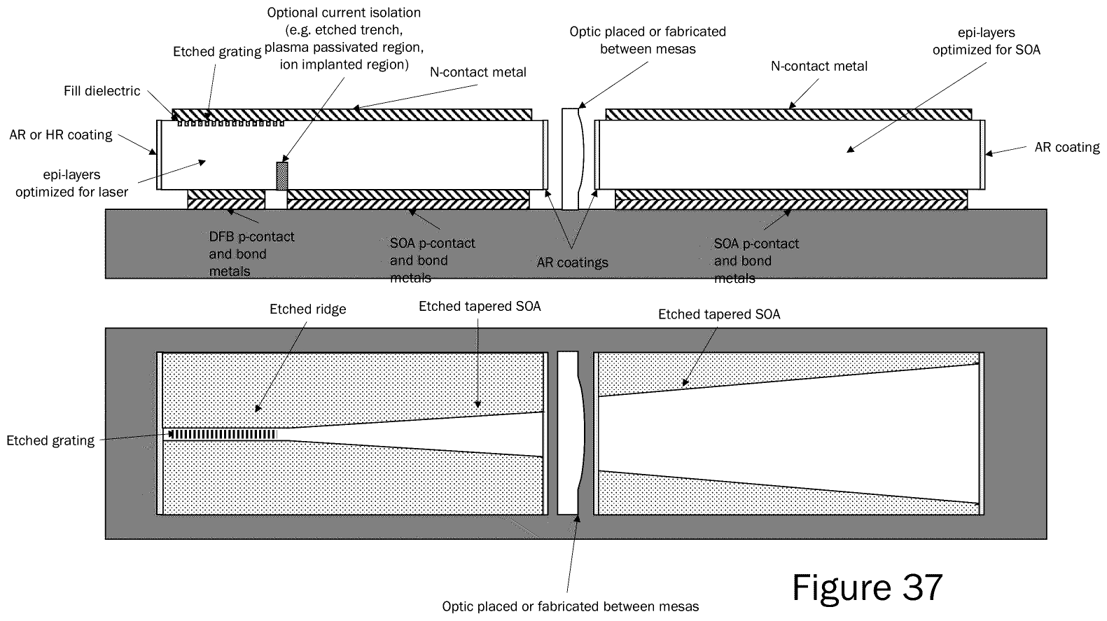

FIG. 37 includes simplified top-view and cross-sectional diagrams of a continuous mesa single-frequency MOPA or laser diode device with a separate mesa amplifier according to an example of the present invention. This example is similar to that of FIG. 34 with an optic arranged or formed between the mesas to improve coupling efficiency.

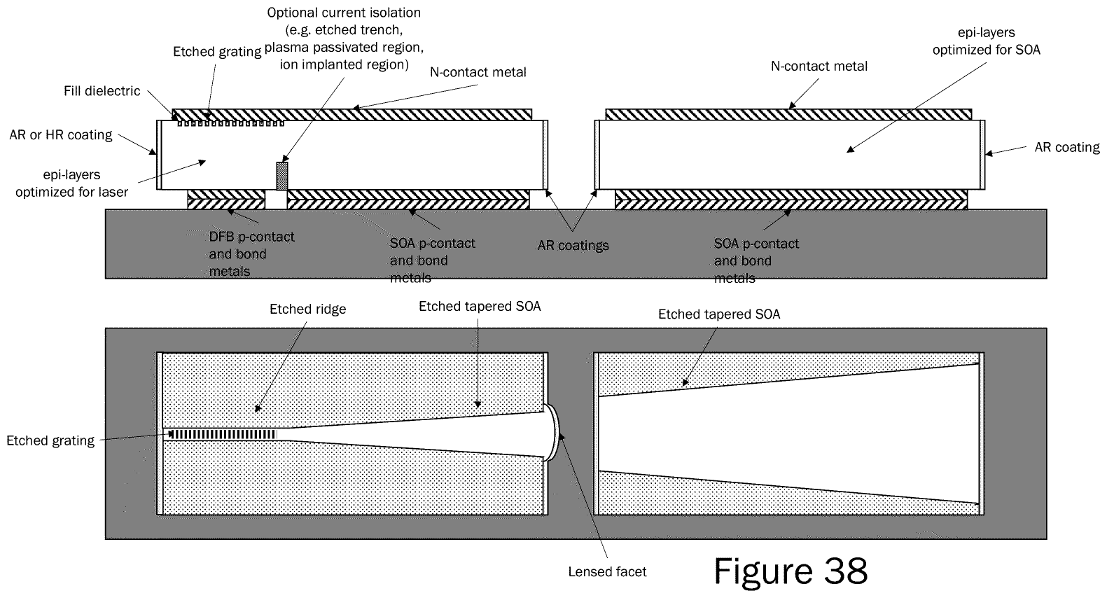

FIG. 38 includes simplified top-view and cross-sectional diagrams of a continuous mesa single-frequency MOPA or laser diode device with a separate mesa amplifier according to an example of the present invention. This example is similar to that of FIG. 34 with a lensed facet formed at an output of the amplifier section to improve coupling efficiency.

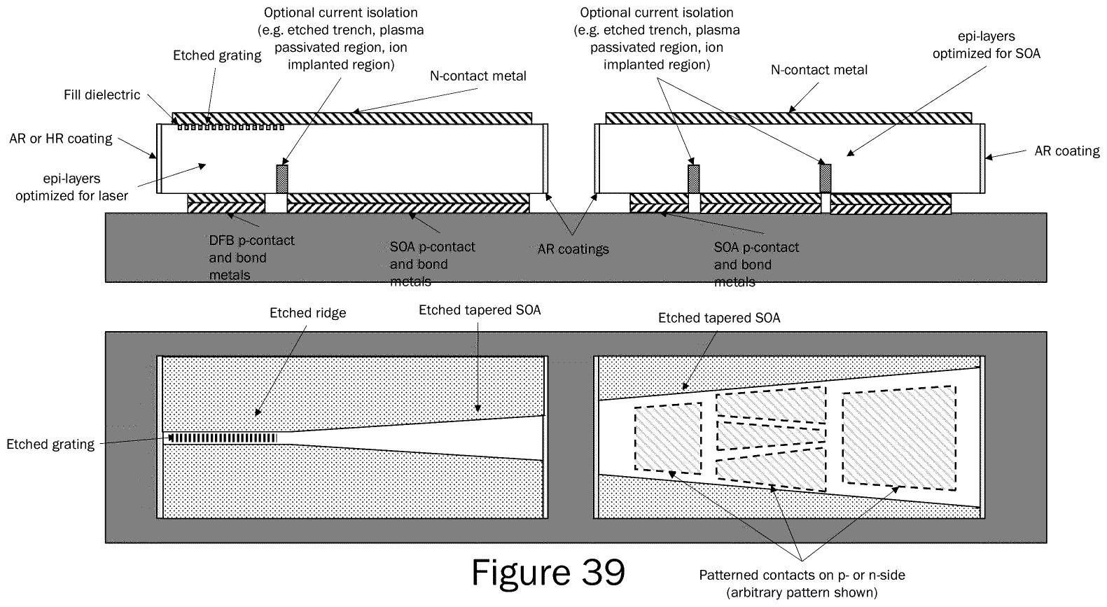

FIG. 39 includes simplified top-view and cross-sectional diagrams of a continuous mesa single-frequency MOPA or laser diode device with a separate mesa amplifier according to an example of the present invention. This example is similar to that of FIG. 34 with patterned contacts on the separate mesa amplifier. Also, one or more current isolation features may be included in the separate mesa amplifier.

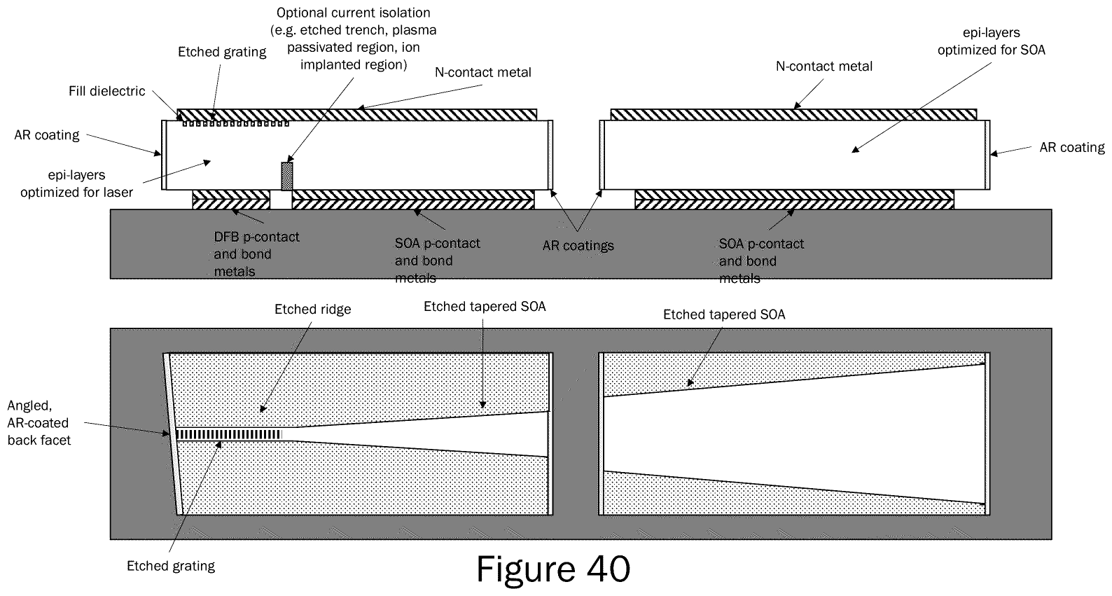

FIG. 40 includes simplified top-view and cross-sectional diagrams of a continuous mesa single-frequency MOPA or laser diode device with a separate mesa amplifier according to an example of the present invention. This example is similar to that of FIG. 34 with an angled back facet on the MOPA region or laser diode device.

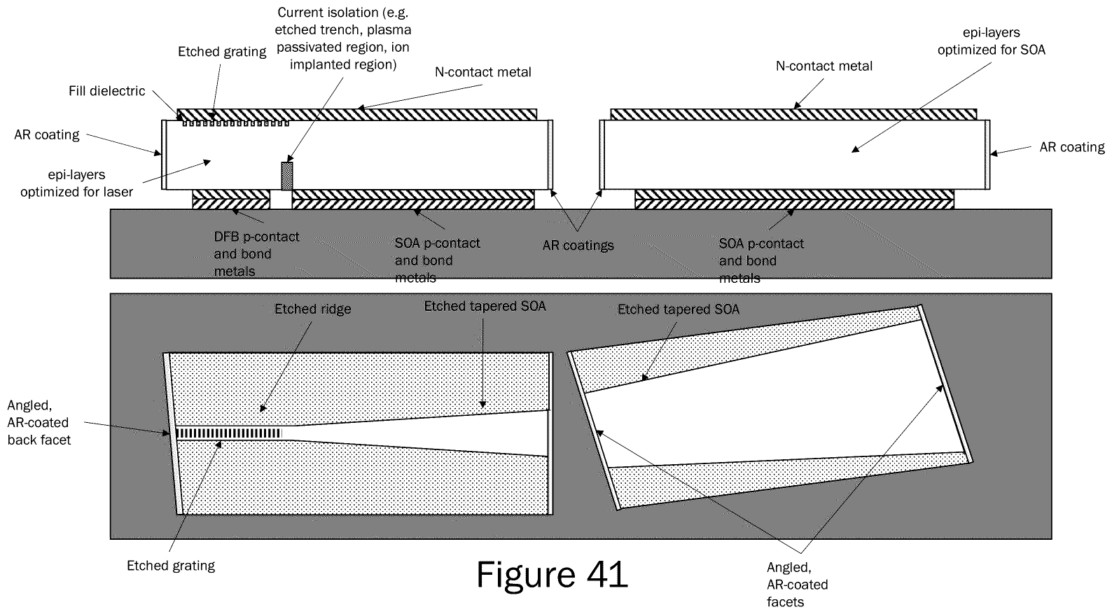

FIG. 41 includes simplified top-view and cross-sectional diagrams of a continuous mesa single-frequency MOPA or laser diode device with a separate mesa amplifier according to an example of the present invention. This example is similar to that of FIG. 40 with one or more angled facets on the separate mesa amplifier. The separate mesa amplifier may be formed at an angle to the MOPA region or laser diode device.

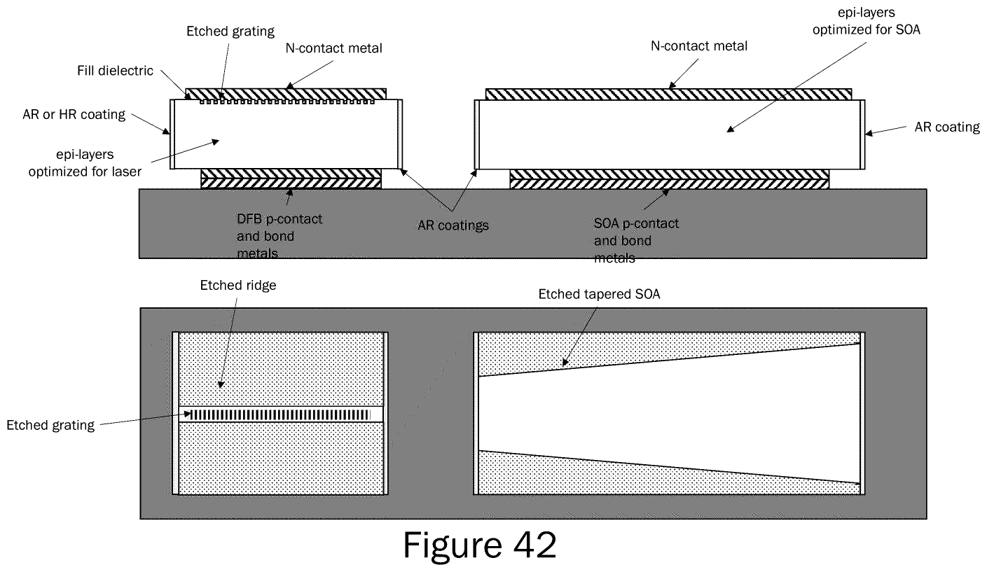

FIG. 42 includes simplified top-view and cross-sectional diagrams of a continuous mesa single-frequency MOPA or laser diode device with a separate mesa amplifier according to an example of the present invention. This example is similar to that of FIG. 34 without a tapered amplifier between the MOPA region or laser diode device and the separate mesa amplifier.

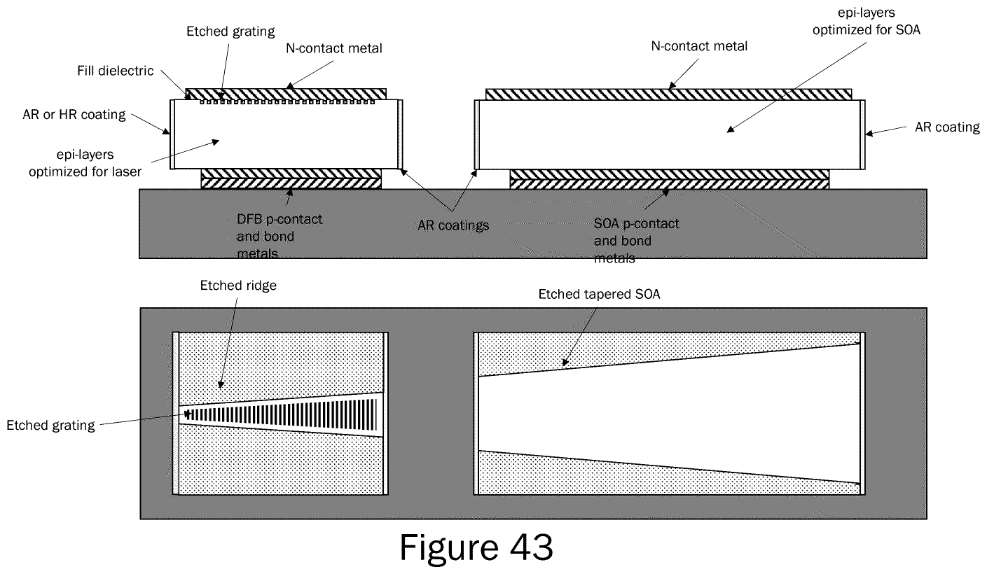

FIG. 43 includes simplified top-view and cross-sectional diagrams of a continuous mesa single-frequency MOPA or laser diode device with a separate mesa amplifier according to an example of the present invention. This example is similar to that of FIG. 43 with a tapered MOPA region or laser diode device.

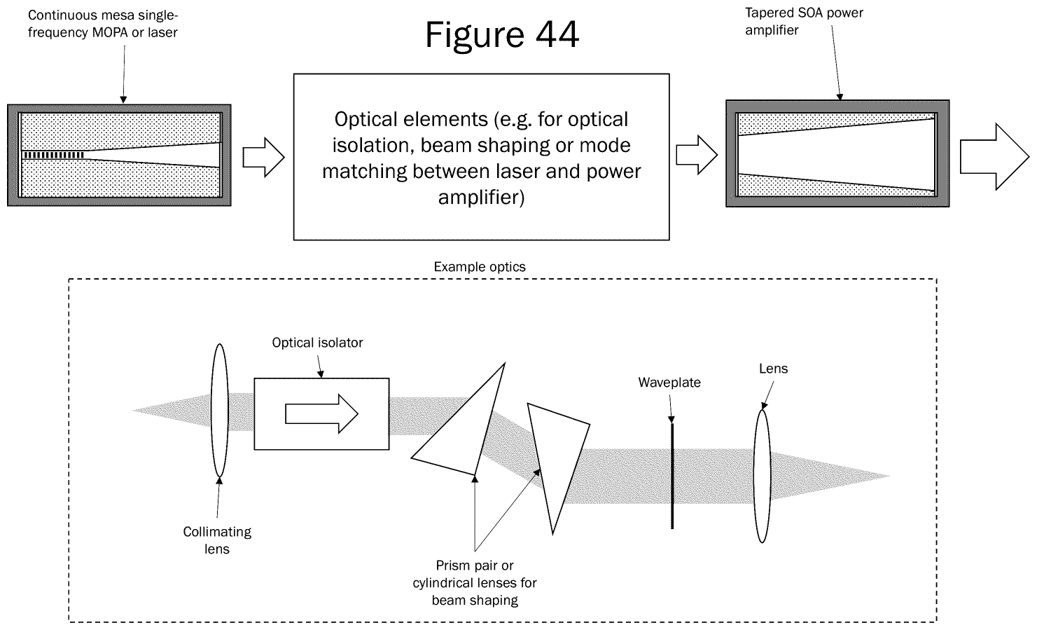

FIG. 44 includes simplified top-view and block diagrams of a continuous mesa single-frequency MOPA or laser diode device with a separate mesa amplifier according to an example of the present invention. This example is similar to that of FIG. 34 except the separate amplifier is a discrete device that is coupled to an output of the MOPA or laser diode device via optics. The MOPA or laser diode device and the separate amplifier may be arranged in a multi or single chip configuration. The optics may include one or more collimating lenses, isolators, wave plates, prisms, lenses, and the like. The optics may provide optical isolation, beam shaping, and/or mode matching between the laser and power amplifier.

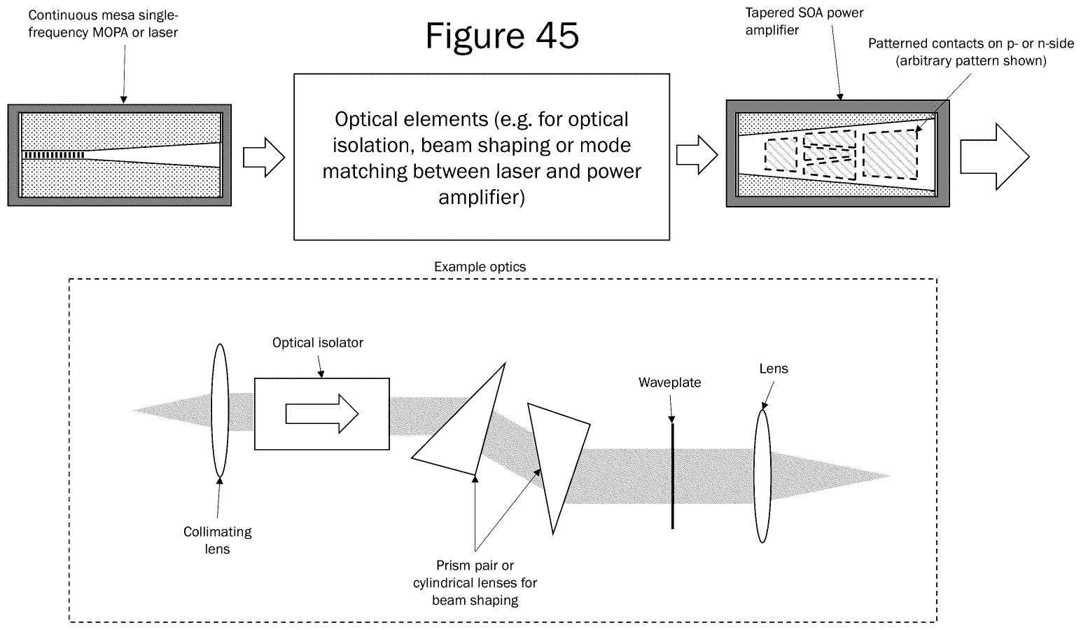

FIG. 45 includes simplified top-view and block diagrams of a continuous mesa single-frequency MOPA or laser diode device with a separate mesa amplifier according to an example of the present invention. This example is similar to that of FIG. 44 with patterned contacts on the separate mesa amplifier.

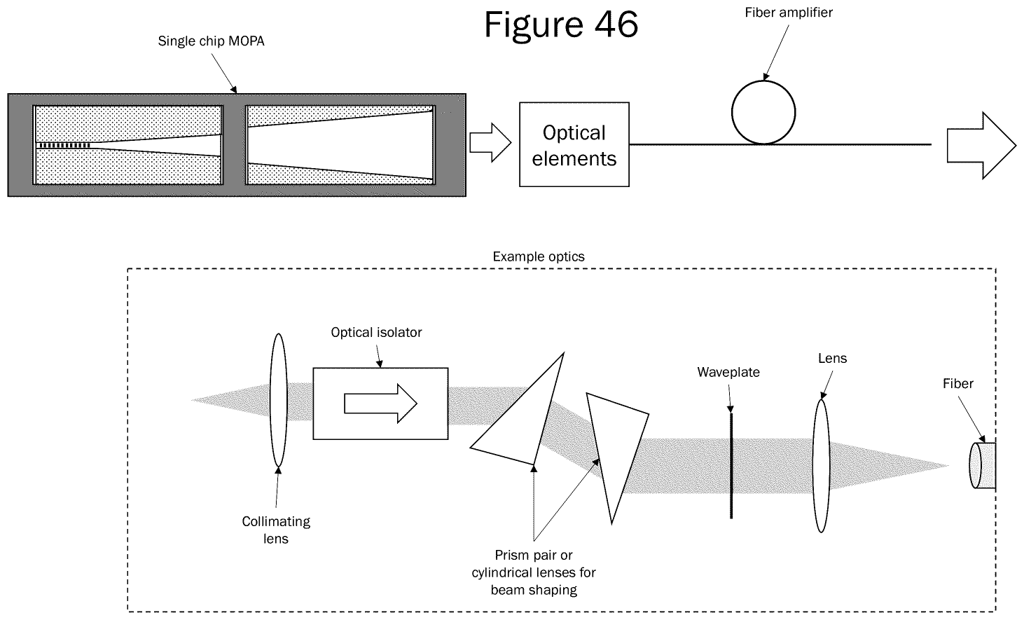

FIG. 46 includes simplified top-view and block diagrams of a continuous mesa single-frequency MOPA or laser diode device with a separate mesa amplifier according to an example of the present invention. This example is similar to that of FIG. 44 except the optics couple output from the separate mesa amplifier with a discrete fiber amplifier.

As used herein, the term GaN substrate is associated with Group III-nitride based materials including GaN, InGaN, AlGaN, or other Group III containing alloys or compositions that are used as starting materials. Such starting materials include polar GaN substrates (i.e., substrate where the largest area surface is nominally an (h k l) plane wherein h=k=0, and l is non-zero).

As used herein, the term substrate is associated with both GaN substrates as well as substrates on which can be grown epitaxially GaN, InGaN, AlGaN, or other Group III containing alloys or compositions that are used as starting materials. Such substrates include SiC, sapphire, silicon and germanium, among others. Substrate may also refer to substrates on which can be grown epitaxially GaAs, AlAs, InAs, GaP, AlP, InP, or other like Group III containing alloys or compositions that are used as starting materials. Such substrates include GaAs, GaP, Ge and Si, among others.

As used herein, the terms carrier or carrier wafer refer to wafer to which epitaxial device material is transferred. The carrier may be composed of a single material and be either single crystalline or polycrystalline. The carrier may also be a composite of multiple materials. For example, the carrier could be a silicon wafer of standard dimensions, or it could be composed of polycrystalline AlN.

As shown, the present device can be enclosed in a suitable package. Such package can include those such as in TO-38 and TO-56 headers. Other suitable package designs and methods can also exist, such as TO-9 or flat packs where fiber optic coupling is required and even non-standard packaging. In a specific embodiment, the present device can be implemented in a co-packaging configuration.

While the above is a full description of the specific embodiments, various modifications, alternative constructions and equivalents may be used. As an example, the packaged device can include any combination of elements described above, as well as outside of the present specification. As used herein, the term “substrate” can mean the bulk substrate or can include overlying growth structures such as a gallium and nitrogen containing epitaxial region, or functional regions such as n-type GaN, combinations, and the like. Additionally, the examples illustrate waveguide structures in normal configurations, there can be variations, e.g., other angles and polarizations. As mentioned, the various beam combining techniques are desirably configured to increase beam intensity efficiently without any detrimental interference between any pair of beams.

### REFERENCES

D. Paboeuf, G. Lucas-Leclin, P. Georges, N. Michel, M. Krakowski, J. Lim, S. Sujecki, and E. Larkins, “Narrow-line coherently combined tapered laser diodes in a Talbot external cavity with a volume Bragg grating,” Appl. Phys. Lett. 93(21), 211102 (2008).
R. K. Huang, B. Chann, L. J. Missagia, S. J. Augst, M. K. Connors, G. W. Turner, A. Sanchez-Rubio, J. P. Donnelly, J. L. Hostetler, C. Miester, and F. Dorsch, “Coherent combination of slab-coupled optical waveguide lasers,” Proc. SPIE 7230, 72301G (2009).
S. M. Redmond, D. J. Ripin, C. X. Yu, S. J. Augst, T. Y. Fan, P. A. Thielen, J. E. Rothenberg, and G. D. Goodno, “Diffractive coherent combining of a 2.5 kW fiber laser array into a 1.9 kW Gaussian beam,” Opt. Lett. 37(14), 2832-2834 (2012).

1.-61. (canceled)

62. A master oscillator power amplifier device containing a gallium and nitrogen containing material, the device comprising:
a carrier substrate member comprising a front side and a back side;
a metal bonding material that is free from solder material overlying the front side of the carrier substrate member and configured to bond an overlying transferred material to the front side of the carrier substrate member;
a p-type contact region overlying the metal bonding material and configured to form a thermal path and an electrical path to and from the metal bonding material;
a p-type gallium and nitrogen containing region overlying the p-type contact region;
an active region overlying the p-type gallium and nitrogen containing region, the active region comprising a plurality of quantum well regions;
an n-type gallium and nitrogen containing region overlying the active region, the n-type gallium and nitrogen containing region comprising a plurality of sub-regions numbered from 1 to N, where Nis an integer of 2 and greater;
a waveguide configured from a portion of the n-type gallium and nitrogen containing region, the waveguide having a first end and a second end; and configured to output a laser beam from one of the first end or the second end;
a stripe region configured from an upper surface of the waveguide;
an n-type contact region overlying the stripe region; and
a first region of the waveguide configured as a master oscillator device and a second region configured as a first power amplifier and coupled to the first region such that the first region and the second region are characterized as a master oscillator first power amplifier device.

63. The device of claim 62 further comprising a spatial pattern disposed on the n-type contact region and configured with a dimension and a geometry to achieve a predetermined mode quality (“M2”).

64. (canceled)

65. The device of claim 63 wherein the spatial pattern is selected from an n-chip pattern, a longitudinal modulated pattern, a lateral modulated pattern, or any combinations thereof.

66.-76. (canceled)

77. The device of claim 62 wherein the waveguide is characterized by a tapered waveguide structure configured as a mesa structure.

78.-81. (canceled)

82. The device of claim 62 wherein the waveguide is characterized by a linear continuous taper section, a bow tie taper shape, a straight section coupled to a continuous taper section, a straight section configured between a pair of tapered sections to form a bow tie shape.

83.-85. (canceled)

86. The device of claim 62 further comprising one or more grating structures configured with the waveguide.

87. The device of claim 86 wherein the waveguide is configured with a width to achieve a spatial mode such that a narrower width relates to a single spatial mode and a wider width relates to multiple modes.

88. The device of claim 62 wherein the first region comprises a plurality of grating structures configured as a distributed feedback structure.

89. The device of claim 62 wherein the first region comprises a distributed Bragg reflector device.

90.-91. (canceled)

92. The device of claim 62 wherein the first region is characterized by a straight waveguide and the second region is characterized by a tapered waveguide.

93. The device of claim 62 further comprising a current isolation region configured between the first region and the second region to electronically isolate the first region from the second region.

94. (canceled)

95. The device of claim 62 further comprising a third region configured as a second power amplifier operably coupled to the first power amplifier and configured with a gap configured between the second region and the third region to separate the second region from the third region.

96.-97. (canceled)

98. The device of claim 62 further comprising a third region configured as a second power amplifier, the third region operably coupled to the second region, the second power amplifier comprising an antireflective coating on an aperture portion, and an antireflective portion coating on an exit portion.

99.-101. (canceled)

102. The device of claim 62 further comprising a third region configured as a second power amplifier, the third region operably coupled to the second region, the third region and the second region being configured with a spatial gap between the second region and the third region; and wherein the first region comprises an angled facet region.

103.-104. (canceled)

105. The device of claim 62 wherein the first end and the second end include mirrors to form a cavity, the cavity configured to propagate electromagnetic radiation through the cavity and output the laser beam from one of the first end or the second end.

106. The device of claim 63 wherein the spatial pattern is configured to achieve a current injection pattern and maintain a filamenting characteristic of the device.

107. The device of claim 63 wherein the spatial pattern is configured to enhance a beam quality from a first level to a second level.

108. The device of claim 62 further comprising a grating structure configured to maintain single cavity mode operation.

109. The device of claim 62 further comprising a waveguide configured to maintain single spatial mode operation.

110. The device of claim 62 further comprising a grating structure, wherein the device is configured for single spatial mode operation and single cavity mode operation to maintain a single frequency.
